(19) United States
(12) Patent Application Publication
(10) Pub. No.: US 2013/0029470 A1
(43) Pub. Date: Jan. 31, 2013

(54) METHOD OF FORMING SEMICONDUCTOR DEVICE

(71) Applicants: Nana HATAYA, Tokyo (JP); Nobuyuki SAKO, Tokyo (JP); Hiroki YAMAWAKI, Tokyo (JP); Shun FUJIMOTO, Tokyo (JP); Jiro MIYAHARA, Tokyo (JP)

(72) Inventors: Nana HATAYA, Tokyo (JP); Nobuyuki SAKO, Tokyo (JP); Hiroki YAMAWAKI, Tokyo (JP); Shun FUJIMOTO, Tokyo (JP); Jiro MIYAHARA, Tokyo (JP)

(73) Assignee: ELPIDA MEMORY, INC., Tokyo (JP)

(21) Appl. No.: 13/280,037

(22) Filed: Oct. 24, 2011

(30) Foreign Application Priority Data
Jul. 26, 2011 (JP) 2011-163135

(51) Int. Cl. H01L 21/02; H01L 21/44

(52) U.S. Cl. 438/396; 438/674; 257/E21.008; 257/E21.476

(57) ABSTRACT

A method of forming a semiconductor device includes the following processes. A dummy insulating film is formed over a semiconductor substrate by using a source material that is free of carbon as an essential component. A hole that penetrates the dummy insulating film is formed. A conductive film is formed, which covers at least a side wall of the hole of the dummy insulating film. The dummy insulating film is removed to expose an outer surface of the conductive film.

### BACKGROUND OF THE INVENTION

1. Field of the Invention

The present invention generally relates to a method of forming a semiconductor device.

Priority is claimed on Japanese Patent Application No. 2011-163135, filed Jul. 26, 2011, the content of which is incorporated herein by reference.

2. Description of the Related Art

In a DRAM (dynamic random access memory), which is one type of semiconductor device, in order to achieve a sufficient electrostatic capacitance in a capacitor element that constitutes a memory cell, the capacitive element is generally formed in a vertical shape.

Specifically, for example, the shape of the lower electrode that constitutes the capacitor element is made a crown shape, so that it is possible to expand the surface areas of the inner wall surface and the outer wall surface of the lower electrode for use as a capacitor element (crown-type capacitor).

In a manufacturing process for a DRAM, in order to expose an outer wall surface of a lower electrode, a sacrificial oxide film, which is formed in a memory cell region by wet etching, and also in which a plurality of lower electrodes are formed, is selectively removed so as to form a space for forming a capacitor (space for forming the capacitive insulating film and upper electrode that will become the capacitor).

In a manufacturing process for a DRAM, in order to expose an outer wall surface of a lower electrode, a sacrificial oxide film, which is formed in a memory cell region by wet etching, and also in which a plurality of lower electrode is formed, is selectively removed so as to form a space for forming a capacitor (space for forming the capacitive insulating film that will become the capacitor (space for forming the capacitive insulating film and an upper electrode that will become the capacitor).

Japanese Patent Application Publication No. JPA 2003-297952 discloses the formation of a BPSG film or a TEOS film as the above-noted sacrificial oxide film (mold oxide film).

### SUMMARY

In one embodiment, a method of forming a semiconductor device is formed. A dummy insulating film is formed over a semiconductor substrate by using a source material that is free of carbon as an essential component. At least a hole that penetrates the dummy insulating film is formed. At least a conductive film is formed, which covers at least a side wall of the hole of the dummy insulating film. The dummy insulating film is removed.

In another embodiment, a method of forming a semiconductor device may include, but is not limited to, the following processes. A dummy insulating film is formed over a semiconductor substrate by using at least a carbon-free source material. At least a hole that penetrates the dummy insulating film is formed. At least a conductive film is formed, which covers at least a side wall of the hole of the dummy insulating film. The dummy insulating film is removed.

In still another embodiment, a method of forming a semiconductor device may include, but is not limited to, the following steps. A dummy insulating film is formed over a semiconductor substrate by using a source material that is free of carbon as an essential component. At least a hole that penetrates the dummy insulating film is formed. At least a conductive film having a first surface adjacent to a side wall of the hole is formed. At least a portion of the dummy insulating film is formed. The portion is adjacent to the first surface of the conductive film, to have the conductive film remain and to expose the first surface of the conductive film.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a fragmentary cross sectional elevation view of a semiconductor device in a step involved in a method of forming the semiconductor device in accordance with a first embodiment of the present invention;

FIG. 2 is a fragmentary cross sectional elevation view of a semiconductor device in a step subsequent to the step of FIG. 1, involved in the method of forming the semiconductor device in accordance with the first embodiment of the present invention;

FIG. 3 is a fragmentary cross sectional elevation view of a semiconductor device in a step subsequent to the step of FIG. 2, involved in the method of forming the semiconductor device in accordance with the first embodiment of the present invention;

FIG. 4A is a fragmentary cross sectional elevation view of a semiconductor device, taken along a C-C line of FIG. 4B, in a step subsequent to the step of FIG. 3, involved in the method of forming the semiconductor device in accordance with the first embodiment of the present invention;

FIG. 4B is a fragmentary cross sectional elevation view of the semiconductor device in the step subsequent to the step of FIG. 3, involved in the method of forming the semiconductor device in accordance with the first embodiment of the present invention;

FIG. 5 is a fragmentary cross sectional elevation view of a semiconductor device in a step subsequent to the step of FIGS. 4A and 4B, involved in the method of forming the semiconductor device in accordance with the first embodiment of the present invention;

FIG. 6A is a fragmentary cross sectional elevation view of a semiconductor device, taken along a D-D line of FIG. 6B, in a step subsequent to the step of FIG. 5, involved in the method of forming the semiconductor device in accordance with the first embodiment of the present invention;

FIG. 6B is a fragmentary cross sectional elevation view of the semiconductor device in the step subsequent to the step of FIG. 5, involved in the method of forming the semiconductor device in accordance with the first embodiment of the present invention;

FIG. 7 is a fragmentary cross sectional elevation view of a semiconductor device in a step subsequent to the step of FIGS. 6A and 6B, involved in the method of forming the semiconductor device in accordance with the first embodiment of the present invention;

FIG. 8 is a fragmentary cross sectional elevation view of a semiconductor device in a step subsequent to the step of FIG. 7, involved in the method of forming the semiconductor device in accordance with the first embodiment of the present invention;

FIG. 9 is a fragmentary cross sectional elevation view of a semiconductor device in a step involved in a method of forming the semiconductor device in accordance with a second embodiment of the present invention;

FIG. 10 is a fragmentary cross sectional elevation view of a semiconductor device in a step subsequent to the step of FIG. 9, involved in the method of forming the semiconductor device in accordance with the second embodiment of the present invention;

FIG. 11 is a fragmentary cross sectional elevation view of a semiconductor device in a step subsequent to the step of FIG. 10, involved in the method of forming the semiconductor device in accordance with the second embodiment of the present invention;

FIG. 12 is a fragmentary cross sectional elevation view of a semiconductor device in a step subsequent to the step of FIG. 11, involved in the method of forming the semiconductor device in accordance with the second embodiment of the present invention;

FIG. 13 is a fragmentary cross sectional elevation view of a semiconductor device in a step subsequent to the step of FIG. 12, involved in the method of forming the semiconductor device in accordance with the second embodiment of the present invention;

FIG. 14 is a fragmentary cross sectional elevation view of a semiconductor device in a step subsequent to the step of FIG. 13, involved in the method of forming the semiconductor device in accordance with the second embodiment of the present invention;

FIG. 15 is a fragmentary cross sectional elevation view of a semiconductor device in a step involved in a method of forming the semiconductor device in accordance with a third embodiment of the present invention;

FIG. 16 is a fragmentary cross sectional elevation view of a semiconductor device in a step subsequent to the step of FIG. 15, involved in the method of forming the semiconductor device in accordance with the third embodiment of the present invention;

FIG. 17 is a fragmentary cross sectional elevation view of a semiconductor device in a step subsequent to the step of FIG. 16, involved in the method of forming the semiconductor device in accordance with the third embodiment of the present invention;

FIG. 18 is a fragmentary cross sectional elevation view of a semiconductor device in a step subsequent to the step of FIG. 17, involved in the method of forming the semiconductor device in accordance with the third embodiment of the present invention; and

FIG. 19 is a fragmentary cross sectional elevation view of a semiconductor device in a step subsequent to the step of FIG. 18, involved in the method of forming the semiconductor device in accordance with the third embodiment of the present invention.

### DETAILED DESCRIPTION OF THE PREFERRED EMBODIMENTS

Before describing the present invention, the related art will be explained, in order to facilitate the understanding of the present invention.

Upon the inventors of the present application studying a method for manufacturing the above-noted crown-type capacitor, it became clear that the following phenomenon exist.

Known methods of forming a sacrificial oxide film do the forming using a raw material that contains a carbon component. For example, a BPSG film is formed from a raw material containing a carbon component, such as TEB (triethyl boron), TEPO (triethyl phosphate), or TEOS (tetraethoxy silane).

As a result of the investigation by the inventors, it was learned that by forming the above-noted BPSG film as the sacrificial oxide film, etching the BPSG film to form a hole, and forming a conducting film that will serve as the lower electrode in the hole, after which wet etching is done to remove the sacrificial oxide film covering the outer wall of the lower electrode, the carbon component contained in the raw material used when forming the BPSG film remains as a residue (carbon residue).

If it is not possible to completely remove all of the residue caused by the carbon component before forming the capacitor insulating film and the upper electrode, the forming of the capacitor insulating film could be poor, resulting in poor capacitor characteristics. If the characteristics of the capacitor worsen in this manner, the yield of the semiconductor device is reduced.

Embodiments of the invention will be now described herein with reference to illustrative embodiments. Those skilled in the art will recognize that many alternative embodiments can be accomplished using the teaching of the embodiments of the present invention and that the invention is not limited to the embodiments illustrated for explanatory purpose.

In one embodiment, a method of forming a semiconductor device is formed. A dummy insulating film is formed over a semiconductor substrate by using a source material that is free of carbon as an essential component. At least a hole that penetrates the dummy insulating film is formed. At least a conductive film is formed, which covers at least a side wall of the hole of the dummy insulating film. The dummy insulating film is removed.

The source material that is free of carbon as an essential component means any source materials that satisfy the following conditions. The dummy insulating film is formed on the conductive film by using a source material free of carbon as an essential component. As comparative examples, TEOS and BPSG films are formed on the conductive film by using carbon-containing-source materials at the same thickness as the dummy insulating film. Carbon residue on the conductive film after the dummy insulating film is removed by a wet etching process is lower than carbon residues on the conductive films after the TEOS and BPSG films are removed by the same wet etching process.

In some cases, forming the dummy insulating film may include, but is not limited to, carrying out a plasma chemical vapor deposition method using a source material comprising monosilane and nitrogen oxide.

In some cases, forming the dummy insulating film may include, but is not limited to, carrying out a high density plasma chemical vapor deposition method using a source material comprising monosilane and oxygen.

In some cases, the method may further include, but is not limited to, forming a second dummy insulating film by using a carbon-containing source material. The second dummy insulating film is contact to the first dummy insulating film. The hole penetrates the first and second dummy insulating films. The second dummy insulating film may be formed either after or before the first dummy insulating film is formed.

In some cases, forming the dummy insulating film may include, but is not limited to, forming a first dummy insulating layer; and forming a second dummy insulating layer on the first dummy insulating layer. The hole penetrates the first and second dummy insulating layers. A first one of forming the first dummy insulating layer and forming the second dummy insulating layer is carried out using a source material comprising monosilane and nitrogen oxide. A second one of forming the first dummy insulating layer and forming the second dummy insulating layer is carried out using a source material comprising monosilane and oxygen. The first one may be either forming the first dummy insulating layer or forming the second dummy insulating layer, while the second one is the other. The second dummy insulating layer may be formed either after or before the first dummy insulating layer is formed.

In some cases, forming the hole may include, but is not limited to, carrying out an anisotropic etching process to selectively etch the first and second dummy insulating layers. The anisotropic etching process for selectively etching the second dummy insulating layer is varied out at a slower etching rate than that of the anisotropic etching process for selectively etching the first dummy insulating layer.

In some cases, removing the dummy insulating film may include, but is not limited to, removing at least a portion of the dummy insulating film, the portion covering an outside surface of the conductive film, to expose the outside surface of the conductive film.

In some cases, the dummy insulating film is removed after the conductive film is formed.

In some cases, the method may further include, but is not limited to, forming a circuit element layer over the semiconductor substrate before forming the dummy insulating film. The circuit element layer may include, but is not limited to, a cell region and a peripheral circuit region. The cell region may include, but is not limited to, a cell transistor. The peripheral circuit region may include, but is not limited to, a peripheral transistor. A capacitive contact pad is formed on the cell region of the circuit element layer. The capacitive contact pad is coupled to the cell transistor. An etching stopper film covering the capacitive contact pad and the circuit element layer is formed. The dummy insulating film is formed on the etching stopper film. The etching stopper film is lower in etching rate than the dummy insulating film.

In some cases, the method may further include, but is not limited to, forming a support film formation insulating film on the dummy insulating film. The support film formation insulating film is lower in etching rate than the dummy insulating film.

In some cases, forming the hole may include, but is not limited to, forming a hole which penetrates the support film formation insulating film, the dummy insulating film and the etching stopper film, so that the hole reaches an upper surface of the capacitive contact pad.

In some cases, forming the conductive film may include, but is not limited to, forming the conductive film which covers the side wall of the hole of the etching stopper film, the dummy insulating film, and the support film formation insulating film. The conductive film covers the capacitive contact pad at the bottom of the hole.

In some cases, forming at least a hole may include, but is not limited to, forming a plurality of holes. Forming the at least one conductive film may include, but is not limited to, forming a plurality of conductive films. The method further may include, but is not limited to, forming a plurality of capacitive insulating films on the plurality of conductive film; and forming a plurality of top electrodes on the plurality of capacitive insulating films to form a plurality of capacitors which include the conductive films as bottom electrodes.

In some cases, the method may further include, but is not limited to, forming a support film by patterning the support film formation insulating film, after forming the plurality of conductive films and before removing the dummy insulating film. The support film connects the plurality of conductive films as the bottom electrodes.

In some cases, forming the support film may further include, but is not limited to, removing the support film formation insulating film entirely in the peripheral circuit region and selectively in the cell region to expose an upper surface of the dummy insulating film in the peripheral circuit region and to expose parts of the upper surface of the dummy insulating film in the cell region. The parts of the upper surface are positioned under gaps between the bottom electrodes.

In some cases, removing the dummy insulating film may further include, but is not limited to, carrying out a wet etching process under conditions such that the support film and the etching stopper film are lower in etching rate than the dummy insulating film, to expose an upper surface of the etching stopper film and outside surfaces of the bottom electrodes.

In some cases, forming the plurality of capacitive insulating films may further include, but is not limited to, forming the capacitive insulating film which covers the upper surface of the etching stopper film, the bottom electrodes and the support film; and forming the top electrode which covers the capacitive insulating film.

In some cases, forming the top electrode may further include, but is not limited to, forming the top electrode which fills inner spaces of the bottom electrodes covered by the capacitive insulating film. The top electrode also fills gaps between the bottom electrodes covered by the capacitive insulating film. The top electrode has a flat top surface.

In another embodiment, a method of forming a semiconductor device may include, but is not limited to, the following processes. A dummy insulating film is formed over a semiconductor substrate by using at least a carbon-free source material. At least a hole that penetrates the dummy insulating film is formed. At least a conductive film is formed, which covers at least a side wall of the hole of the dummy insulating film. The dummy insulating film is removed.

In still another embodiment, a method of forming a semiconductor device may include, but is not limited to, the following steps. A dummy insulating film is formed over a semiconductor substrate by using a source material that is free of carbon as an essential component. At least a hole that penetrates the dummy insulating film is formed. At least a conductive film having a first surface adjacent to a side wall of the hole is formed. At least a portion of the dummy insulating film is formed. The portion is adjacent to the first surface of the conductive film, to have the conductive film remain and to expose the first surface of the conductive film.

The source material that is free of carbon as an essential component means any source materials that satisfy the following conditions. The dummy insulating film is formed on the conductive film by using a source material free of carbon as an essential component. As comparative examples, TEOS and BPSG films are formed on the conductive film by using carbon-containing-source materials at the same thickness as the dummy insulating film. Carbon residue on the conductive film after the dummy insulating film is removed by a wet etching process is lower than carbon residues on the conductive films after the TEOS and BPSG films are removed by the same wet etching process.

### First Embodiment

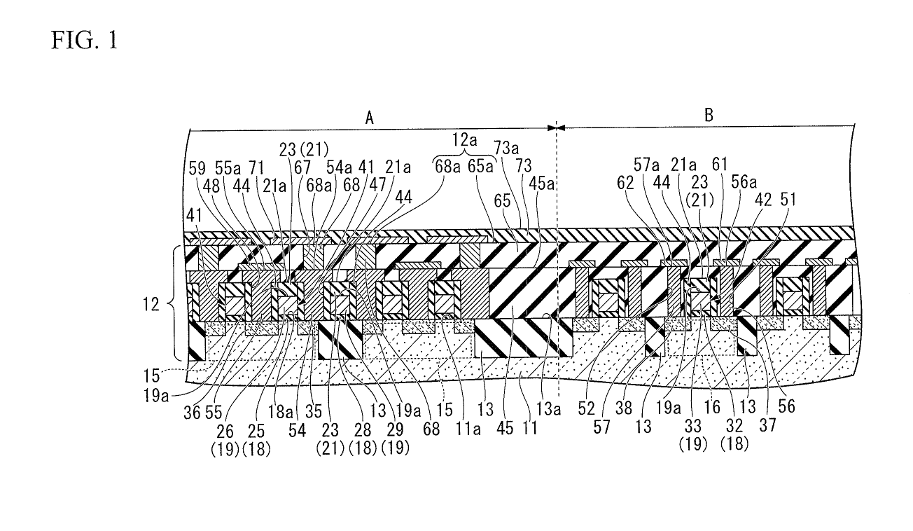

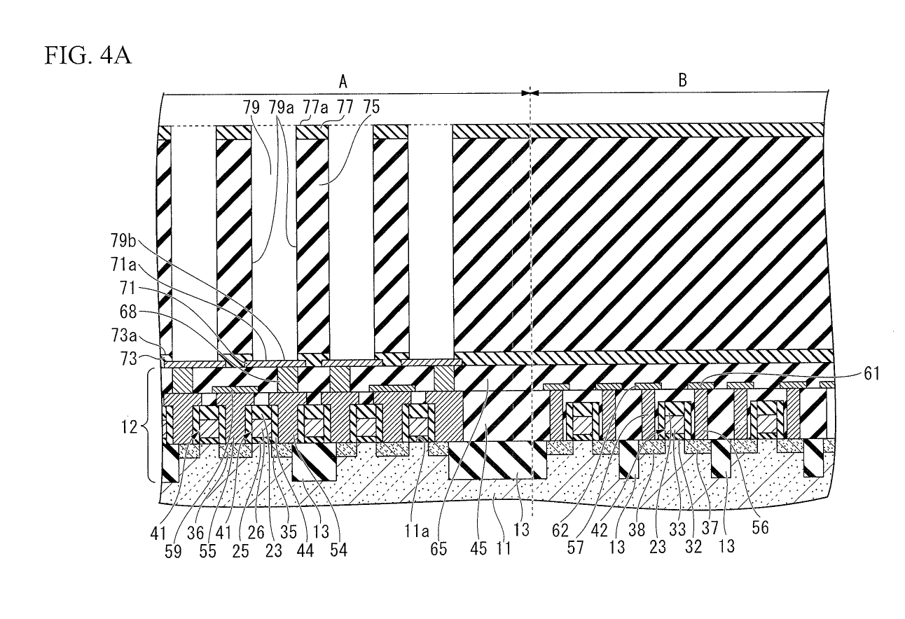

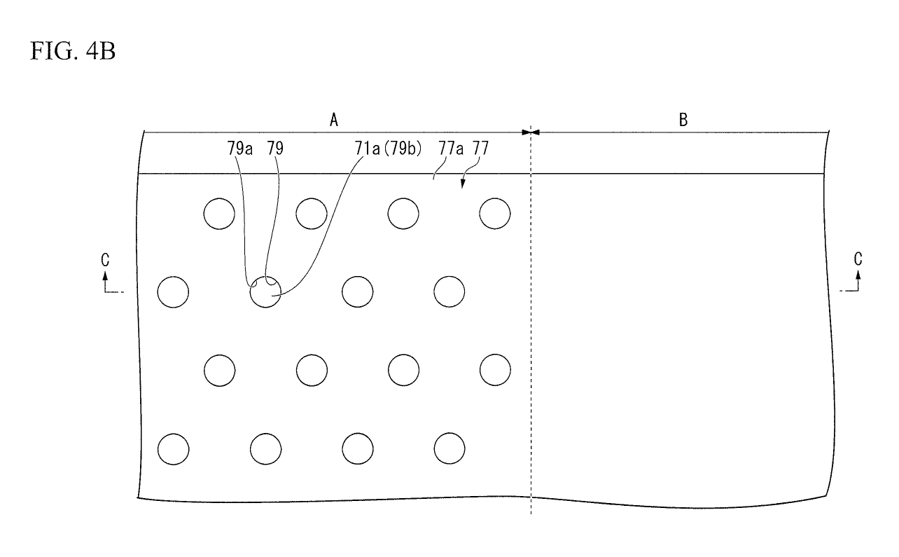

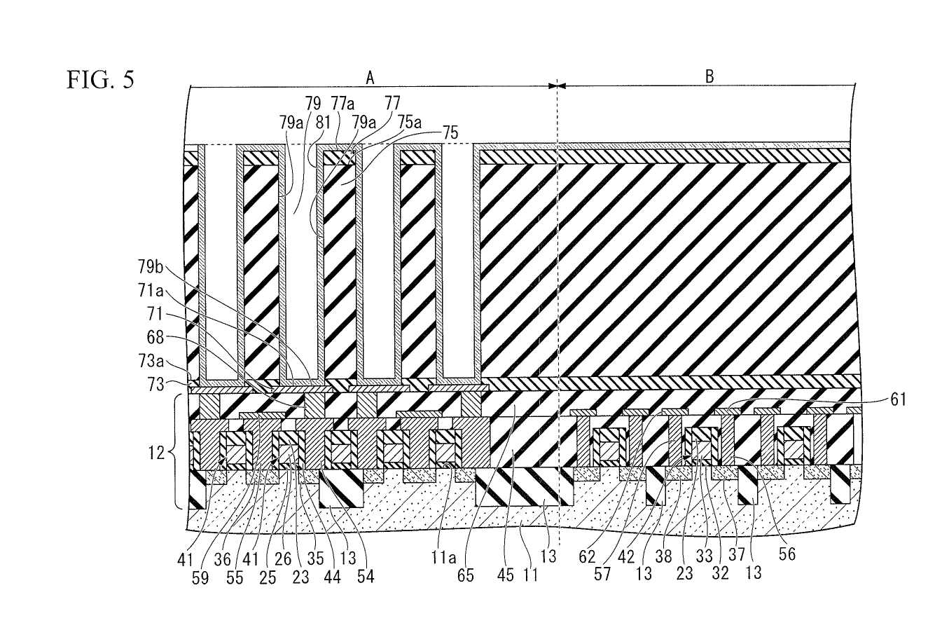

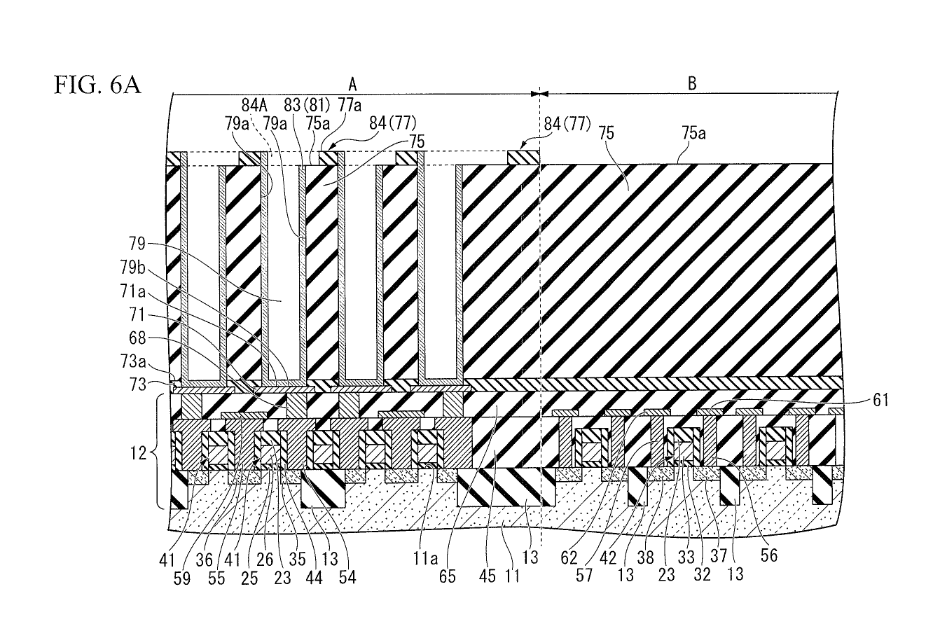

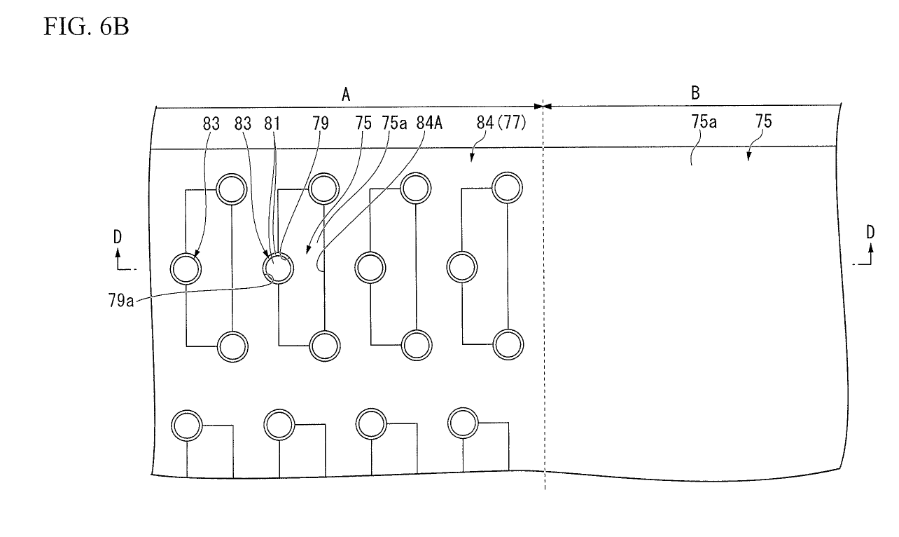

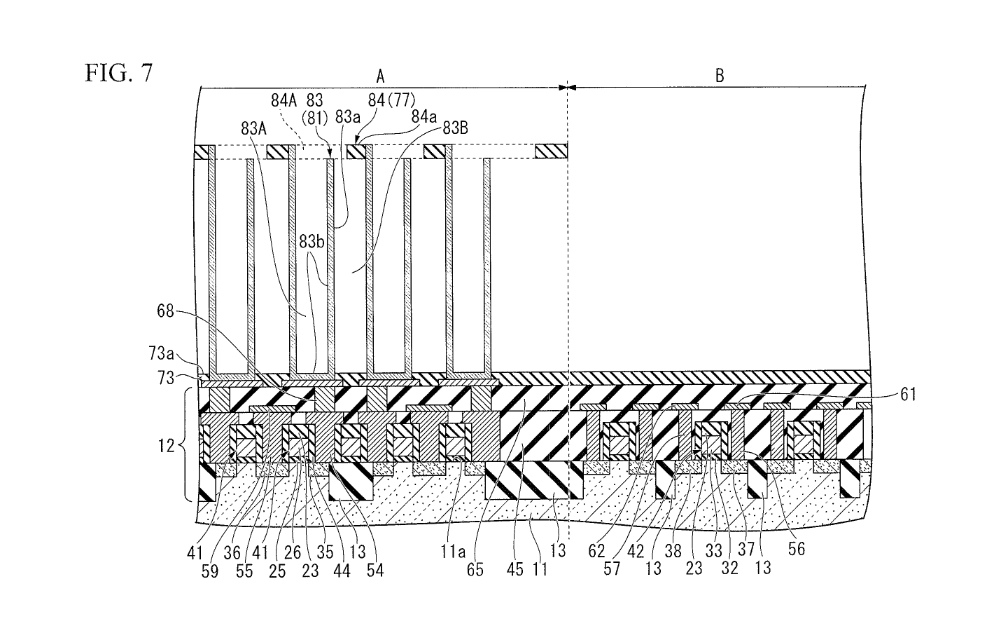

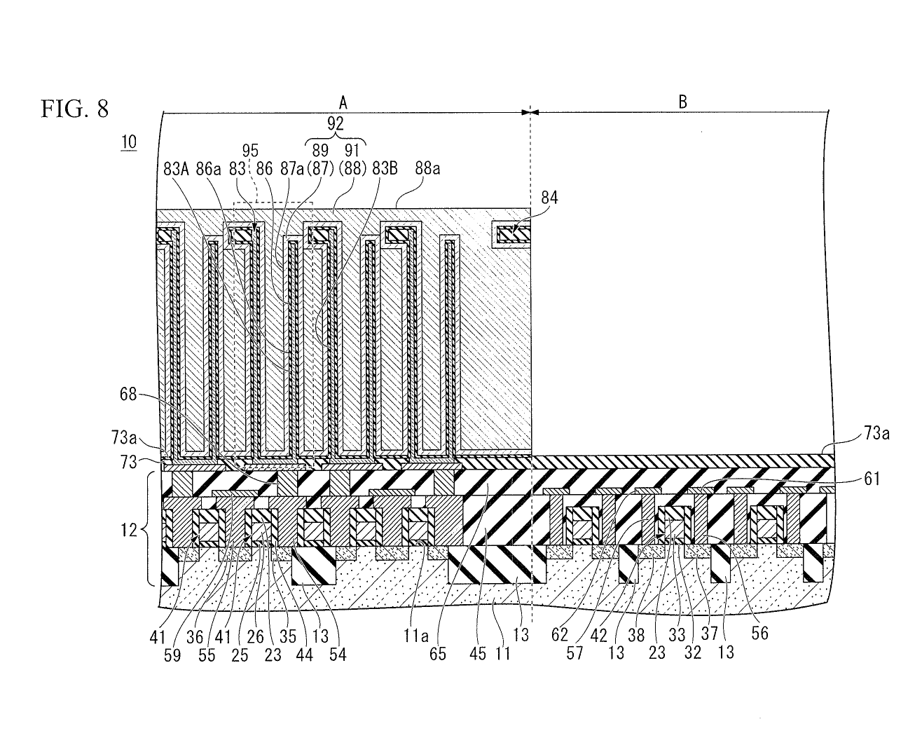

FIG. 1 to FIG. 3, FIG. 4A to FIG. 5, FIG. 6A, FIG. 7, and FIG. 8 are cross-sectional views of the manufacturing processes for a semiconductor device according to the first embodiment of the present invention. FIG. 4B is a plan view of the semiconductor device shown in FIG. 4A being manufactured, and FIG. 6B is a plan view of the semiconductor device shown in FIG. 6A being manufactured.

FIG. 4A is a drawing that corresponds to a cross-sectional view of the semiconductor device manufactured, along the line C-C in FIG. 4B, and FIG. 6A is a drawing that corresponds to a cross-sectional view of the semiconductor device manufactured, along the line D-D in FIG. 6B.

In FIG. 1 to FIG. 3, FIG. 4A, FIG. 4B, FIG. 5, FIG. 6A, FIG. 6B, FIG. 7, and FIG. 8, a DRAM (dynamic random access memory) is illustrated as an example of the semiconductor device 10 (refer to FIG. 8) according to the first embodiment.

The method for manufacturing the semiconductor device 10 according to the first embodiment is described below, with references made to FIG. 1 to FIG. 3, FIG. 4A, FIG. 4B, FIG. 5, FIG. 6A, FIG. 6B, FIG. 7, and FIG. 8.

First, in the process shown in FIG. 1, the semiconductor substrate 11 is prepared. Specifically, for example, a p-type single-crystal silicon substrate is prepared as the semiconductor substrate 11.

In the first embodiment, the description will use the example of using a p-type single-crystal silicon substrate as the semiconductor substrate 11.

A circuit element layer 12 that includes a cell transistor 41 and a peripheral transistor 42 is formed on the semiconductor substrate 11.

Referring to FIG. 1, the process of forming the circuit element layer 11 will be described.

First, an element separation region 13 is formed on the semiconductor substrate 11. When this is done, the element separation region 13 is formed so that the upper surface 13a of the element separation region 13 is substantially flush with the surface 11a of the semiconductor substrate 11. Specifically, the element separation region 13 can be formed, for example, by the STI (shallow trench isolation) method.

An active region 15 partitioned by the element separation region 13 is formed in the semiconductor substrate 11 that is opposite the memory cell region A, and an active region 16 partitioned by the element separation region 13 is formed in the semiconductor substrate 11 that is opposite the peripheral circuit region B.

An insulating film 18 that covers the upper surface 11a of the semiconductor substrate 11 and the upper surface 13a of the element separation region 13 that include the active regions 15 and 16, a gate electrode formation conducting film 19 that cover the upper surface 18a of the insulating film 18, and a capacitor formation insulating film 21 that covers the upper surface 19a of the gate electrode formation conducting film 19 are sequentially laminated.

By patterning the insulating film 18, it becomes a film that will form a first gate insulating film 25, a dummy gate insulating film 28, and a second gate insulating film 32.

As the insulating film 18, it is possible to use, for example, a single-layer silicon oxide film (SiO₂ film), a nitride silicon oxide film (SiON film), a laminated silicon oxide film (SiO₂ film), or a laminated film of a silicon nitride film (SiN film) laminated over a silicon oxide film (SiO₂ film).

As the gate electrode formation insulating film 19, it is possible to use, for example, a laminated film made by sequentially laminating a doped polysilicon film (for example, a polycrystalline silicon film containing phosphorus) and a metal film. As the metal film, it is possible to apply a tungsten film (W film), a tungsten nitride film (WN film), or a tungsten silicide film, which has a high melting point.

As the capacitor formation insulating film 21, a silicon nitride film (SiN film) can be used.

Photoresist (not shown) is formed on the upper surface 21a of the capacitor formation insulating film 21 that corresponds to the formation regions for the first gate electrode 26, the dummy gate electrode 29, and the second gate electrode 33.

By anisotropic etching (specifically, dry etching) using the photoresist as an etching mask, the capacitor formation insulating film 21 is etched, so as to form the capacitor insulating film 23 in the memory cell region A and the peripheral circuit region B, after which the photoresist is removed.

Anisotropic etching (specifically, dry etching) is done using the capacitor insulating film 23 as a mask, so as to pattern the gate electrode formation conducting film 19 and the insulating film 18.

In the memory cell region A, two structures in which the first gate insulating film 25, the first gate electrode 26, and the capacitor insulating film 23 are sequentially laminated are formed so as to be opposite one another. On the upper surface 13a of the element separation region 13 disposed between the active regions 15, one structure is formed in which the dummy gate electrode insulating film 28, the dummy gate electrode 29, and the capacitor insulating film 23 are sequentially laminated.

Additionally, in the peripheral circuit region B, one structure in which the second gate insulating film 32, the second gate electrode 33, and the capacitor insulating film 23 are sequentially formed on the active region 16.

Using the first and second gate electrodes 26 and 33 as masks, an impurity is ion-implanted into the active regions 15 and 16. Specifically, phosphorus (P), which is an n-type impurity, is ion-implanted into the active regions 15 and 16.

In the memory cell region A, a first impurity diffusion region 35 is formed in the active region 15 at a position that is between the first gate electrode 26 and the element separation region 13, and a second impurity diffusion region 36 is formed in the active region 15 at a position between the first gate electrodes.

In the peripheral circuit region B, a third impurity diffusion region 37 is formed in one of the active regions 16 positioned between the second gate electrode 33 and the element separation region 13, and a fourth impurity diffusion region 38 is formed in the other.

In the memory cell region A, a cell transistor 41 is formed, which is constituted by the first gate insulating film 25, the first gate electrode 26, the first impurity diffusion region 35, and the second impurity diffusion region 36. Also, in the peripheral circuit region B, a peripheral transistor 42 is formed, which is constituted by the second gate insulating film 32, the second gate electrode 33, the third impurity diffusion region 37, and the fourth impurity diffusion region 38. The cell transistor 41 is a transistor used for selection in a DRAM cell.

The second impurity diffusion region 36 functions as a source/drain region that is common to two cell transistors 41 that are at adjacent positions.

By depositing a silicon nitride film (SiN film) from the surface 11a side of the semiconductor substrate 11 by using CVD, and then etching back is performed of the silicon nitride film, the silicon nitride film on a side wall of a structure constituted by the first gate insulating film 25 and the first gate electrode 26, on a side wall of a structure constituted by the dummy gate insulating film 28 and the dummy gate electrode 29, and on a side wall of a structure constituted by the second gate insulating film 32 and the second gate electrode 33 are caused to remain, thereby forming a side wall 44 that is made of a silicon nitride film.

On the upper surfaces of the first to the fourth impurity diffusion regions 35 to 38 and the upper surface 13a of the element separation region 13, a first interlayer insulating film 45 having a thickness that covers the capacitor insulating film 23 and the side wall 44 and also having a flat upper surface 45a is formed.

Specifically, a silicon oxide film (SiO₂ film) that forms the base material of the first interlayer insulating film 45 is formed by CVD, after which CMP (chemical mechanical polishing) is performed to polish the upper surface side of the silicon oxide film (SiO₂ film), thereby forming a first interlayer insulating film 45 having an upper surface 45a that is flat.

Patterned photoresist (not shown) is formed on the upper surface 45a of the first interlayer insulating film 45, and anisotropic etching (specifically, dry etching) is performed using the photoresist as an etching mask, so as to form, in one process, a first contact hole 47 that exposes the upper surface of the first impurity diffusion region 35, a second contact hole 48 that exposes the upper surface of the second impurity diffusion region 36, a third contact hole 51 that exposes the upper surface of the third impurity diffusion region 37, and a fourth contact hole 52 that exposes the upper surface of the fourth impurity diffusion region 38. The first and second contact holes 47 and 48 are formed by the SAC (self-aligned contact) method. After this, the photoresist (not shown) is removed.

By filling the first to the fourth contact plugs 54 to 57 with a conducting film for forming a contact plug (not shown), the first contact plug 54 that makes contact with the upper surface of the first impurity diffusion region 35, the second contact plug 55 that makes contact with the upper surface of the second impurity diffusion region 36, the third contact plug 56 that makes contact with the upper surface of the third impurity diffusion region 37, and the fourth contact plug 57 that makes contact with the upper surface of the fourth impurity diffusion region 38 are formed in one process.

When this is done, the first to fourth contact plugs 54 to 57 are formed so that the upper surfaces 54a, 55a, 56a, and 57a of the first to fourth contact plugs 54 to 57 are substantially flush with respect to the upper surface 45a of the first interlayer insulating film 45.

A bit line 59 connected the upper surface 55a of the second contact plug 55, a first interconnect 61 connected to the upper surface 56a of the third contact plug 56, and a second interconnect 62 connected to the upper surface 56a of the third contact plug 56 are formed in one process on the upper surface 45a of the first interlayer insulating film 45.

Specifically, the bit line 59, the first interconnect 61, and the second interconnect 62 are, for example, formed by the following method. First, a tungsten nitride film (WN film) and a tungsten film (W film) are sequentially formed so as to cover the upper surface 45a of the first interlayer insulating film 45, and the upper surfaces 54a, 55a, 56a, and 57a of the first to fourth contact plugs 54 to 57.

Patterned photoresist (not shown) is formed over the tungsten film (W film). Then, anisotropic etching (specifically, dry etching) is done using the photoresist as a mask to remove unnecessary parts of the tungsten nitride film (WN film) and tungsten film (W film), so as to form the bit line 59, the first interconnect 61, and the second interconnect 62 made of the tungsten nitride film (WN film) and the tungsten film (W film) in one process.

The bit line 59 is electrically connected to the second impurity diffusion region 36, via the second contact plug 55. Also, the first interconnect 61 is electrically connected to the third impurity diffusion region 37, via the third contact plug 56, and the second interconnect 62 is electrically connected to the fourth impurity diffusion region 38, via the fourth contact plug 57.

Also the conducting film that will be the base material of the bit line 59, the first interconnect 61, and the second interconnect 62 is not restricted to the above-described laminated film made of the tungsten nitride film (WN film) and the tungsten film (W film).

A second interlayer insulating film 65 is formed on the upper surface 45a of the first interlayer insulating film 45, so as to cover the bit line 59, the first interconnect 61, and the second interconnect 62, and also so as to have a flat upper surface 65a.

Specifically, a silicon oxide film (SiO₂ film) that forms the base material of the second interlayer insulating film 65 is formed by CVD, after which CMP is performed to polish the upper surface side of the silicon oxide film (SiO₂ film), thereby forming a second interlayer insulating film 65 having an upper surface 65a that is flat.

Photolithography and dry etching are used to etch the second interlayer insulating film 65 formed on the first contact plug 54 so as to form a capacitor contact hole 67 that exposes the upper surface 54a of the first contact plug 54.

A plurality of capacitor contact plugs 68 are formed so as to fill the capacitor contact hole 67 and so as to have upper surfaces 68a that are substantially flush with respect to the upper surface 65a of the second interlayer insulating film 65.

Specifically, the capacitor contact plug 68 is formed, for example, by the following method. First, using CVD, a titanium film (Ti film) is formed on the inner surface of the capacitor contact hole 67, and then, using CVD, a titanium nitride film (TiN film) is formed so as to cover the surface of the titanium film (Ti film).

When this is done, the titanium film (Ti film) and the titanium nitride film (TiN film) are formed so that the total thickness of the titanium film (Ti film) and the titanium nitride film (TiN film) is a thickness that does not fill the capacitor contact hole 67.

Using CVD, a tungsten film (W film) having a thickness that fills the capacitor contact hole 67 is formed on the surface of the titanium nitride film (TiN film).

Using CVD, of the titanium film (Ti film), the titanium nitride film (TiN film), and the tungsten film (W film), the part that is formed higher than the upper surface 65a of the second interlayer insulating film 65 is polished away, so as to form a capacitor contact plug 68 made of a titanium film (Ti film), a titanium nitride film (TiN film), and a tungsten film (W film) on the inside of the capacitor contact hole 67.

The capacitor contact plug 68, by making contact with the upper surface 54a of the first contact plug 54, is electrically connected to the first impurity diffusion region 35 via the first contact plug 54.

A circuit element layer 12 having an element separation region 13, active regions 15 and 16, a capacitor insulating film 23, a dummy gate insulating film 28, a dummy gate electrode 29, a cell transistor 41, a peripheral transistor 42, a side wall 44, a first interlayer insulating film 45, first to fourth contact plugs 54 to 57, a bit line 59, a first interconnect 61, a second interconnect 62, a second interlayer insulating film 65, a capacitor contact hole 67, and a capacitor contact plug 68 is formed over the semiconductor substrate 11.

Of the upper surface 12a of the circuit element layer 12 (the surface made of the upper surface 65a of the second interlayer insulating film 65 and the upper surface 68a of the capacitor contact plug 68), a plurality of capacitor contact pads 71 electrically connected to the cell transistor 41 are formed in the memory cell region A in which the cell transistor 41 is formed.

The capacitor contact pad 71 is formed, for example, by the following method. Using CVD, a tungsten nitride film (TN film) is formed so as to cover the upper surface 12a of the circuit element layer, and then, using CVD, a tungsten film (W film) is formed so as to cover the upper surface of the tungsten nitride film (WN film).

Using photolithography and dry etching, the tungsten nitride film (WN film) and the tungsten film (W film) are patterned, so as to form a capacitor contact pad 71 made of the tungsten nitride film (WN film) and the tungsten film (W film).

A capacitor contact pad 71 is formed with respect to the upper surface 68a of each of the capacitor contact plugs 68.

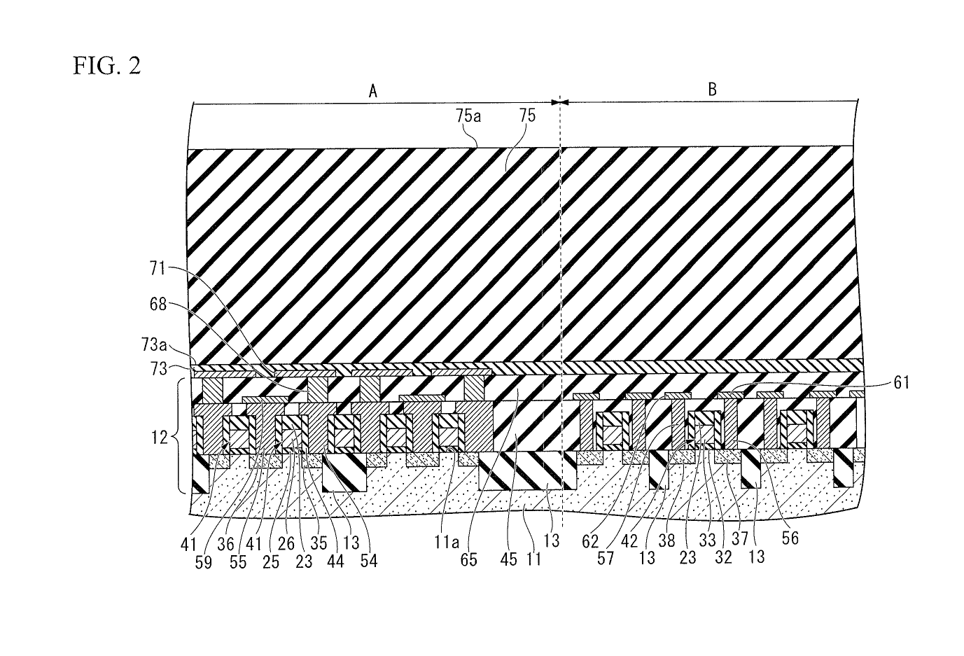

On the upper surface 12a of the circuit element 12, an etching stopper film 73 is formed so as to cover the plurality of capacitor contact pads 71 and so as to have an etching rate that is slower than that of the sacrificial insulating film 75 shown in FIG. 2 to be described later.

A silicon nitride film (SiN film) is deposited as the etching stopper film 73. The etching stopper film 73 is a film (that is, a film for protecting the circuit element layer 12) for the purpose of preventing etching of the first and second interlayer insulating films 45 and 65 of the circuit element layer 12 formed on the lower layer of the sacrificial insulating film 75 when removing the sacrificial insulating film 75 by wet etching in the process step shown in FIG. 7 to be described later.

In the process shown in FIG. 2, using CVD or high-density plasma (HDP) CVD, with a raw material that does not include carbon component, a sacrificial insulating film 75 (for example having a thickness of 1.4 μm) is formed that coverts the upper surface 73a of the etching stopper film 73.

In the case in which CVD is used, for example, monosilane (SiH₄) and N₂O (raw material including oxygen) is used as the raw material not including a carbon component to form a sacrificial insulating film 75 made of a silicon oxide film (SiO₂ film).

In this case, the film deposition conditions can be, for example, a semiconductor substrate 11 temperature of 350 to 400° C., a monosilane (SiH₄) flow amount of 500 to 600 sccm, an N₂O flow amount of 8,000 to 10,000 sccm, and a deposition chamber internal pressure of 360 Pa.

In the case of using high-density plasma CVD, a sacrificial insulating film 75 made of a silicon oxide film (SiO₂ film) is formed using, for example, a raw material of monosilane (SiH₄) and O₂ (raw material including oxygen) as a raw material not including a carbon component.

In this case, the film deposition conditions for the sacrificial insulating film 75 can be, for example, a semiconductor substrate 11 temperature of 80 to 150° C., a monosilane (SiH₄) flow amount of 200 to 210 sccm, an O₂ flow amount of 350 to 360 sccm, and a deposition chamber internal pressure of 0.4 Pa.

The case of forming a silicon oxide film (SiO₂ film) as the sacrificial insulating film 75 is described below as an example.

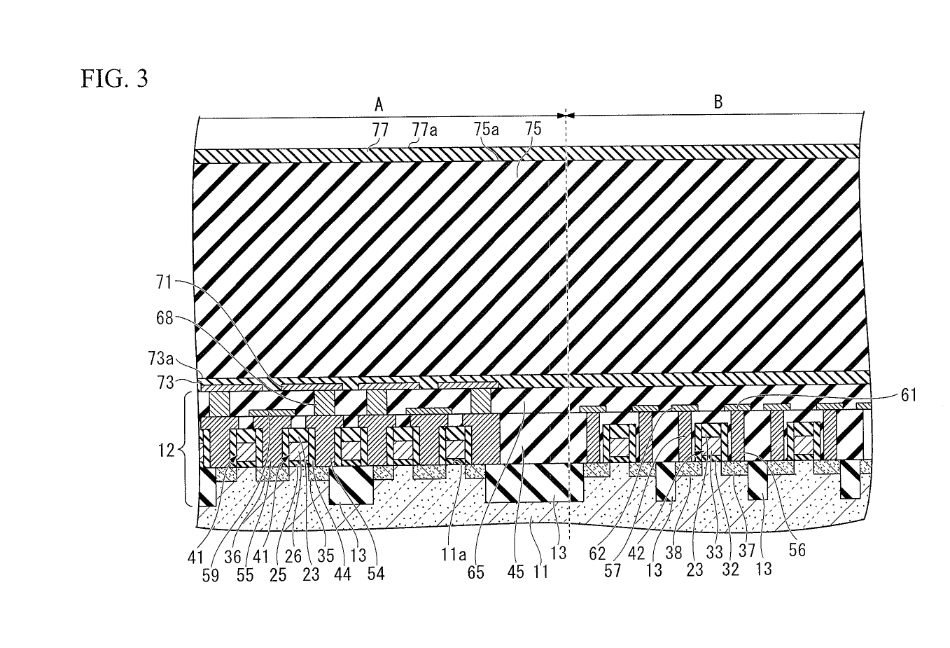

In the process shown in FIG. 3, a support film formation insulating film 77 having an etching rate that is slower than that of the sacrificial insulating film 75 is formed on the upper surface 75a of the sacrificial insulating film 75.

By forming a silicon nitride film (SiN film) on the upper surface 75a of the sacrificial insulating film 75, a support film formation insulating film 77 made of a silicon nitride film (SiN film) is formed.

In the process shown in FIG. 4A and FIG. 4B, using photoresist and dry etching, of the sacrificial insulating film 75 and the support film formation insulating film 77, a hole 79 that passes through the part positioned above the capacitor contact pad 71 and that exposes the upper surface 71a of the capacitor contact pad 71 is formed. A hole 79 is formed with respect to each area above the plurality of capacitor contact pads 71.

In the process shown in FIG. 5, from the upper surface side of the structure shown in FIG. 4A and FIG. 4B, of the upper surface 71a of the capacitor contact pad 71 opposite the bottom surface 79b of the hole 79 and the sacrificial insulating film 75, a conducting film 81 is formed so as to cover the side wall part 79b of the hole 79 (specifically, the etching stopper film 73 exposed in the hole 79, and the side wall parts of the sacrificial insulating film 75 and the support film formation insulating film 77).

For example, using CVD, by sequentially laminating a titan film (Ti film) and a titanium nitride film (TiN film), a conducting film 81 made of the titanium film (Ti film) and the titanium nitride film (TiN film) is formed.

When this is done, the conducting film 81 is formed also on the upper surface 77a of the support film formation insulating film 77. In the first embodiment, the conducting film 81 is a film that serves as the base material for the lower electrode 83 shown in FIG. 6A to be described later.

In the process shown in FIG. 6A and FIG. 6B, photoresist and dry etching are used to selectively remove the conducting film 81 formed on the upper surface 77a of the support film formation insulating film 77, thereby forming a lower electrode 83 made of the conducting film 81 on the inner surface of the plurality of holes 79.

Using photoresist and drying etching, by patterning the support film formation insulating film 77, a support film 84 having the support film formation insulating film 77 as a base material and linking to the upper ends of the plurality of lower electrodes 83 is formed.

In the process that forms the support film 84, the support film formation insulating film 77 formed on the peripheral circuit region B is completely removed, and a part of the support film formation insulating film 77 formed on the memory cell region A is removed.

The upper surface 75a of the sacrificial insulating film 75 formed on the peripheral circuit region B is exposed, and a plurality of apertures 84A that expose parts of the upper surface 75a of the sacrificial insulating film 75 positioned between the plurality of lower electrodes 83 are formed in the support film 84. The support film 84 is linked to the upper end of the plurality of lower electrodes 83.

In the process shown in FIG. 7, the sacrificial insulating film that covers the outer wall of the lower electrodes 83 (conducting film 81) shown in FIG. 6A and FIG. 6B is removed, thereby exposing the lower electrodes 83.

Specifically, wet etching under conditions in which the support film 84 and the etching stopper film 73 are more difficult to etch than the sacrificial insulating film 75 is done to remove sacrificial insulating film 75 that remained in the memory cell region A and the peripheral circuit region B shown in FIG. 6A and FIG. 6B, so as to expose the upper surface 73a of the etching stopper film 73 and the outer wall surface 83a of the lower electrode 83.

When this is done, because the etching stopper film 73 functions as a stopper for the wet etching, it is possible to prevent damage to the circuit element layer 12 formed below the etching stopper film 73. Hydrogen fluoride solution (HF solution), for example, can be used as the etching chemical for the wet etching.

In this manner, the sacrificial insulating film 75 is formed on the upper surface 73a of the etching stopper film 73 by a deposition method that uses a raw material that does not include a carbon component, after which a hole 79 is formed that passes through the sacrificial insulating film 75. Then, of the sacrificial insulating film 75, a lower electrode 83 made of the conducting film 81 is formed that covers the side wall part 79a and the bottom surface 79b of the hole 79, after which the sacrificial insulating film 75 is removed. By doing this, it is possible to reduce the residue caused by a carbon component being attached to the conductive film 81 after the removal of the sacrificial insulating film 75.

Therefore, it is possible to suppress the poor formation of the capacitor insulating film 86 and the upper electrode 92 that are formed on the surface of the lower electrode 83 (the surface that includes the outer wall surface 83a and the inner surface 83b of the lower electrode 83) and to improve the capacitance value, while reducing the leakage of the stored electrical charge.

Since the characteristics of the capacitor 95 that is constituted by the lower electrode 83, the capacitor insulating film 86, and the upper electrode 92 are improved, the yield of the semiconductor device 10 can be improved (refer to FIG. 8, described later).

In the process shown in FIG. 8, a capacitor insulating film 86 is formed that covers the upper surface 73a of the etching stopper film 73, the surface (the surface that includes the outer wall surface 83a and the inner surface 83b) of the lower electrode 83, and the support film 84 formed in the memory cell region A and the peripheral circuit region B.

Specifically, CVD or ALD (atomic layer deposition) is used to deposit, for example, high-dielectric film such as a hafnium oxide film (HfO₂ film), a zirconium oxide film (ZrO₃ film), an aluminum oxide film (Al₂O₃ film), or laminated body thereof, thereby forming the capacitor insulating film 86.

When this is done, although not shown in FIG. 8, the capacitor insulating film 86 is formed also on the peripheral circuit region B.

A first conducting film 87 that will serve as the base material for the upper electrode 92 (specifically, the base material for the upper electrode body 89) is deposited so as to cover the surface 86a of the capacitor insulating film 86, and then a second conducting film 88 that will serve as the base material for the upper electrode 92 (specifically, the base material for a plate electrode 91) is deposited so as to cover the surface 87a of the first conducting film 87.

When this is done, the first and second conducting films 87 and 88 are formed to a thickness that fills the space 83A within the lower electrode 83 in which the capacitor insulating film 86 is formed, and the space 83B between the lower electrodes 83 in which the capacitor insulating film 86 is formed. The second conducting film 88 is formed so that the upper surface 88a thereof is flat.

The first and second conducting films 87 and 88 are formed also on the surface of the capacitor insulating film 86 (not shown) formed in the peripheral circuit region B.

Specifically, using CVD or ALD, the first conducting film 87 is formed by depositing a titanium nitride film (TiN film). When this is done, the first conducting film 87 is formed to a thickness that does not fill the space 83A within the lower electrode 83.

Sequential deposition is done of a polysilicon film (B-DOPOS) that includes B (boron), and a tungsten film (W film), so as to form a laminated second conducting film 88.

Of the upper surface 88a of the second conducting film 88, a silicon oxide film (SiO₂ film) (not shown) is formed that covers the surface positioned in the memory cell region A, is patterned so as to expose the surface at the position of the peripheral circuit region B, and will serve as an etching mask.

By anisotropic etching (specifically, dry etching) using the silicon oxide film (SiO₂ film) as an etching mask, the capacitor insulating film 86, the first conducting film 87, and the second conducting film 88 formed on the peripheral circuit region B are removed.

A plurality of capacitors 95 constituted by a lower electrode 83, a capacitor insulating film 86, and an upper electrode body 89 made of the first conducting film 87, and the plate electrode 91 made of the second conducting film 86 are formed in the memory cell region A.

Subsequently, the silicon oxide film (SiO₂ film) (not shown) that was used as the etching mask is removed.

In this manner, by not forming a guard ring that surrounds the sacrificial insulating film 75 formed in the memory cell region A between the memory cell region A and the peripheral circuit region B on the etching stopper film 73, compared with a semiconductor device in which the guard ring is formed, it is possible to increase the region in which the capacitor 95 can be formed, enabling an increase in the capacitance of the capacitor 95 with the same chip size as in the past.

Also, although it is not illustrated, a third interlayer insulating film (for example, a silicon oxide film (SiO₂ film) is deposited from the upper surface side of the structure shown in FIG. 8, after which CMP is used to polish the upper surface side of the third interlayer insulating film (not shown), so as to form an upper surface that is positioned above the upper surface 88a of the second conducting film 88 and also that is planarized on the third interlayer insulating film.

A contact plug (not shown) that passes through the third interlayer insulating film and that also reaches the first interconnect 61 disposed in the peripheral circuit region B, and a contact plug (not shown) that passes through the third interlayer insulating film and also that reaches the second interconnect 62 disposed in the peripheral circuit region B are formed.

After the above, of the upper surface of the third interlayer insulating film, an interconnect (not shown) that is electrically connected to the upper electrode 92 is formed on the surface at a position in the memory cell region A and, of the upper surface of the third interlayer insulating film, an interconnect (not shown) is formed that is connected to a contact plug (not shown) passing through the third interlayer insulating film on the surface positioned in the peripheral circuit region B.

The semiconductor device 10 of the first embodiment is manufactured. In FIG. 8, the above-noted third interlayer insulating film, the contact plug passing through the above-noted third interlayer insulating film, and the interconnect formed on the third interlayer insulating film are omitted.

According to the method for manufacturing a semiconductor device of the first embodiment, using a deposition method that uses a raw material that does not include a carbon component, a sacrificial insulating film 75 is formed on the upper surface 73a of the etching stopper film 73 formed on the circuit element layer 12, after which a hole 79 passing through the sacrificial insulating film 75 is formed, and then, of the sacrificial insulating film, a lower electrode 83 made of the conducting film 81 is formed that covers the side wall part 79a and the bottom surface 79b of the hole 79, after which the sacrificial insulating film 75 is removed, so that it is possible to reduce the residue caused by a carbon component being attached to the conductive film 81 after the removal of the sacrificial insulating film 75.

Therefore, it is possible to suppress the poor formation of the capacitor insulating film 86 and the upper electrode 92 that are formed on the surface of the lower electrode 83 (the surface that includes the outer wall surface 83a and the inner surface 83b of the lower electrode 83) and to improve the capacitance value, while reducing the leakage of the stored electrical charge, thereby improving the yield of the semiconductor device 10.

Also, there are cases in which, of the memory cell region A, a conducting film that constitutes the lower electrode, the capacitor insulating film, and a guard film made of a conducting film that constitutes the upper electrode are formed so as to surround one the same group of memory cells, with the only the part of the sacrificial insulating film formed at a position inside the guard ring being removed.

Even in the above-noted case, it is possible to apply the method for manufacturing the semiconductor device 10 of the first embodiment, and it is possible to achieve the same type of effect as the semiconductor device 10 according to the first embodiment.

The application of the method for manufacturing the semiconductor device 10 according to the first embodiment when applied to a semiconductor device 10 having a structure in which the guard ring is not formed has a greater effect, because more of the sacrificial insulating film 75 is removed.

The inventors, through their own investigation clearly identified the fact that it is possible for a carbon residue to remain after the removal of the sacrificial insulating film. The investigation additionally verified that such a carbon residue can influence the element characteristics.

The inventors conceived of the application of a film deposition method that uses a raw material that does not include a carbon component as a method for forming the sacrificial insulating film that is to be removed later.

The method of forming the silicon oxide film (for example, a TEOS film or a BPSG film) using a raw material that contains a carbon component is less expensive than the film deposition method using a raw material that does not include a carbon component as described regarding the first embodiment.

Therefore, it would be natural for a person skilled in the art to think to select a TEOS film or a BPSG film, as a silicon oxide film such as a sacrificial insulating film that is removed later, as noted in the Japanese Patent Application Publication No. JPA 2003-297952.

### Second Embodiment

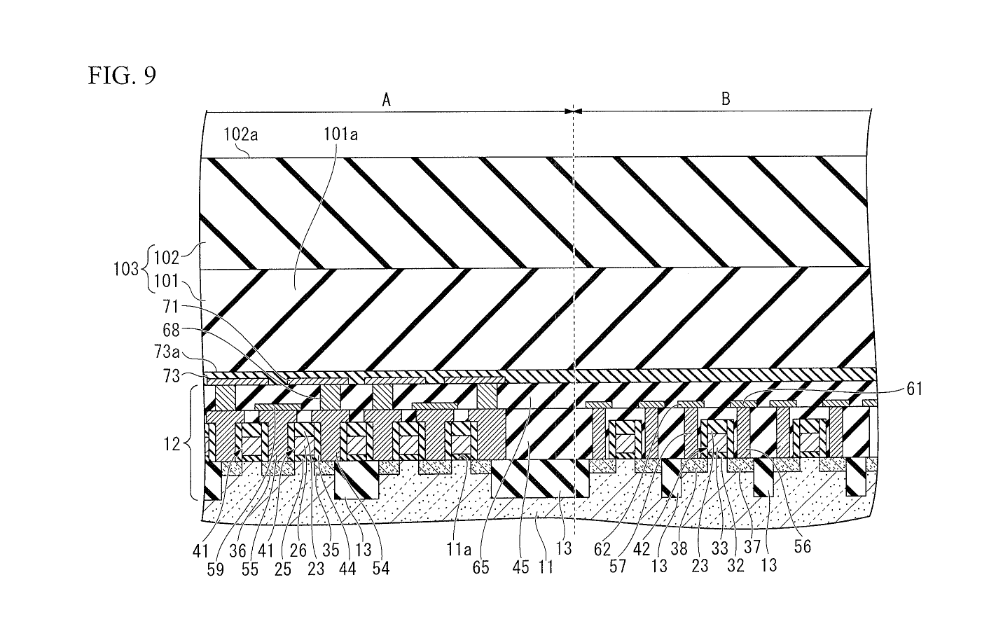

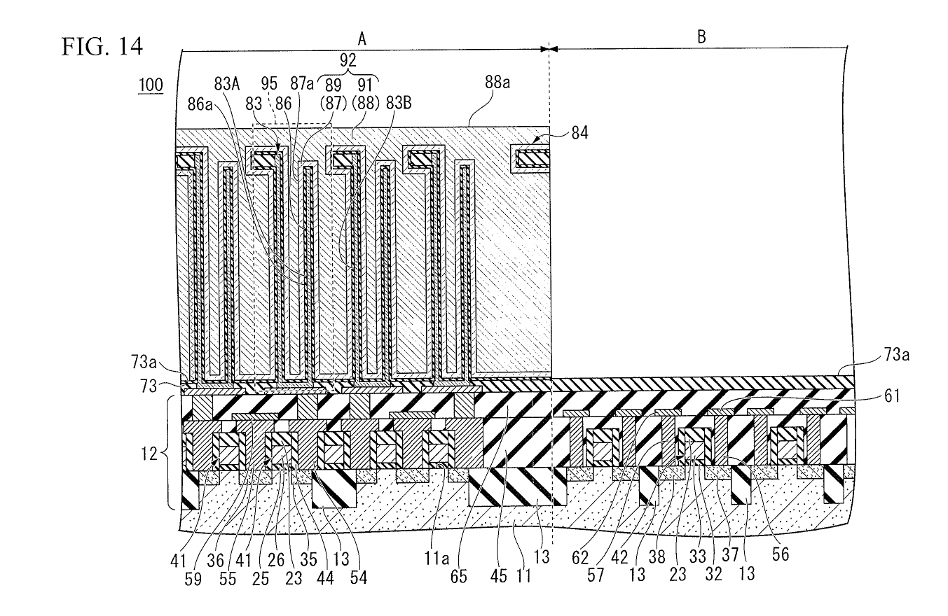

FIG. 9 to FIG. 14 are cross-sectional views of the manufacturing processes for a semiconductor device according to the second embodiment of the present invention. In FIG. 9 to FIG. 14, a DRAM (dynamic random access memory) is illustrated as an example of the semiconductor device 100 (refer to FIG. 14) according to the second embodiment, which is described below. In FIG. 9 to FIG. 14, constituent elements that are the same as those in the semiconductor device 10 of the above-described first embodiment are assigned the same reference numerals.

Referring to FIG. 9 to FIG. 14, the method for manufacturing the semiconductor device 100 according to the second embodiment will be described below.

In the process shown in FIG. 9, using a method similar to that described regarding FIG. 2 in the first embodiment, a circuit element layer 12, a capacitor contact pad 71, and an etching stopper film 73 are sequentially formed on the upper surface 11a of the semiconductor substrate 11.

Plasma CVD using monosilane (SiH₄), which is a raw material that does not include carbon, and a raw material that includes nitrogen oxide (N₂O) is used to form a first sacrificial insulating film 101 (to a thickness of, for example, 0.6 μm) made of a silicon oxide film (SiO₂ film), so as to cover the upper surface 73a of the etching stopper film 73.

In this case, the deposition conditions for the first sacrificial insulating film 101 can be, for example, a semiconductor substrate 11 temperature of 350 to 400° C., a monosilane (SiH₄) flow amount of 500 to 600 sccm, an N₂O flow amount of 8,000 to 10,000 sccm, and a deposition chamber internal pressure of 360 Pa.

High-density plasma CVD using monosilane (SiH₄), which is a raw material that does not include a carbon component, and O₂ (a raw material that includes oxygen) is used to form a second sacrificial insulating film 102 (to a thickness, for example, of 0.8 μm) made of a silicon oxide (Si₂O) film on the surface 101a of the first sacrificial insulating film 101.

A sacrificial insulating film 103 is formed by the sequential lamination of the first sacrificial insulating film 101 and the second sacrificial insulating film 102.

In the case of forming the second sacrificial insulating film 102 using high-density plasma CVD, the film conditions used to deposit the second sacrificial insulating film 102 can be, for example, a semiconductor substrate 11 temperature of 80 to 150° C., a monosilane (SiH₄) flow amount of 200 to 210 sccm, an O₂ flow amount of 350 to 360 sccm, and a deposition chamber internal pressure of 0.4 Pa.

In this manner, by using plasma CVD using a raw material that includes monosilane (SiH₄) and nitrogen oxide (N₂O) to form the first sacrificial insulating film 101, and using high-density plasma CVD using monosilane (SiH₄) and oxygen (O₂) (a raw material that includes oxygen) to form the second sacrificial insulating film 102, it is possible to make the etching rate of the second sacrificial insulating film 102 slower than that of the first sacrificial insulating film 101.

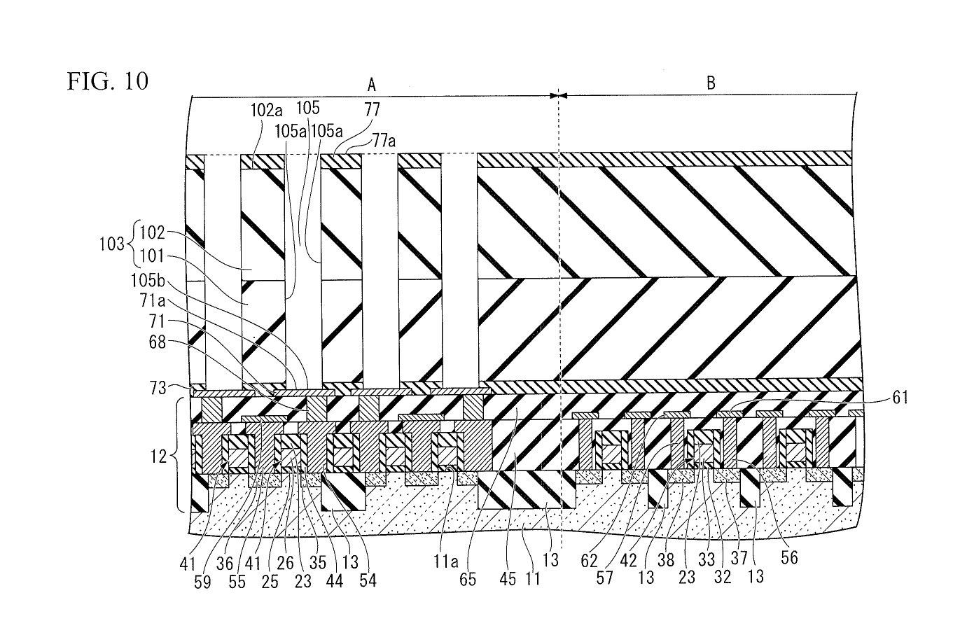

In the process shown in FIG. 10, by performing the same processing as shown in FIG. 3 that was described regarding the first embodiment, a support film formation insulating film 77 is formed.

Photoresist and anisotropic etching (dry etching) are used to form, a hole 105 that exposes the upper surface 71a of the capacitor contact pad 71 and passes through a part of the sacrificial insulating film 103 and support film formation insulating film 77 that is positioned above the capacitor contact pad 71. The hole 105 is formed with respect to each of the plurality of capacitor contact pads 71.

In general when using dry etching to form a hole, the side wall of the hole has a diameter that decreases in a taper shape from the top end of the hole toward the bottom end of the hole. For this reason, in particular in the case of forming a hole with a high aspect ratio using dry etching, because the etching time at the top of the hole is longer than that at the bottom of the hole, the hole tends to spread laterally at the top (the aperture diameter becoming larger at the top) of the hole.

For this reason, in the case of using dry etching to form a plurality of holes in proximity that have a small aperture and also a high aspect ratio, there is a risk of contacting (joining as one) between adjacent holes.

Also, in the case of dry etching an insulating film to form a high aspect ratio hole so as to expose the upper surface of a conductor (for example, a capacitor contact pad), there is a risk that a hole is formed to a depth that does not reach the upper surface of the conductor (for example, a capacitor contact pad). This because of the micro-loading effect, which tends to occur as the aperture diameter becomes small.

In the second embodiment, a first sacrificial insulating film 101 and a second sacrificial insulating film 102 having an etching rate that is slower than that of the first sacrificial insulating film 101 are sequentially laminated on the upper surface 73a of the etching stopper film 73 that covers the capacitor contact pad 71, after which the first and second sacrificial insulating films 101 and 102 are dry etched to form a hole 105 that exposes the upper surface 71a of the capacitor contact pad 71.

That is, at the top part of the hole 105, which has a longer etching time than the bottom part of the hole 105 and tends to widen laterally, a second sacrificial insulating film 102 having a etching rate that is slower than that of the first sacrificial insulating film 101 is formed at the bottom part of the hole 105.

Even in the case of a high aspect ratio hole 105, by the second sacrificial insulating film 102 it is possible to suppress the lateral widening of the top part of the hole 105.

Therefore, even in the case of using dry etching to form a plurality of closely spaced holes 105 having a small aperture diameter in the sacrificial insulating film 103 that is constituted by the first and second sacrificial insulating films 101 and 102, it is possible to suppress contacting between adjacent holes 105.

Stated differently, it is possible to suppress contacting between lower electrodes 83 that are formed in adjacent holes 105, thereby enabling an improvement in the yield of the semiconductor device 100.

Also, by forming a first sacrificial insulating film 101 that has an etching rate that is faster than that of the second sacrificial insulating film 102 as the insulating film formed at the bottom of the hole 105, the etching rate when the bottom of the hole 105 is formed is improved, and dry etching is facilitated. For this reason, it is possible to cause the bottom of the hole 105 to precisely reach the upper surface 71a of the capacitor contact pad 71 within the surface of the semiconductor substrate 11.

It is possible to improve the electrical connection reliability between the bottom end of the lower electrode 83 formed in the hole 105 and the capacitor contact pad 71, thereby enabling an improvement in the yield of the semiconductor device 100.

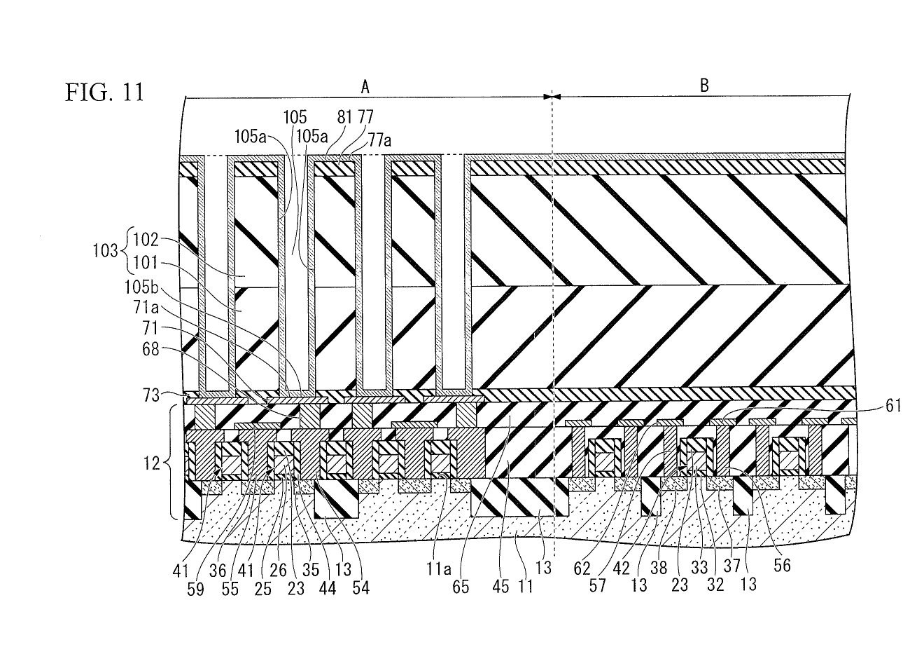

In the process shown in FIG. 11, from the upper surface side of the structure shown in FIG. 10, of the upper surface 71a of the capacitor contact pad 71 and the sacrificial insulating film 103 opposite the bottom surface 105b of the hole 105, a conducting film 81 is formed so as to cover the side wall part 105a of the hole 105 (specifically, the etching stopper film 73 exposed in the hole 105, the sacrificial insulating film 103, and the side wall parts of the support film formation insulating film 77).

CVD is used to sequentially laminate, for example, a titanium film (Ti film) and a titanium nitride film (TiN film), so as to form a conducting layer 81 made of the titanium film (Ti film) and the titanium nitride film (TiN film). When this is done, the conducting film 81 is formed also on the upper surface 77a of the support film formation insulating film 77.

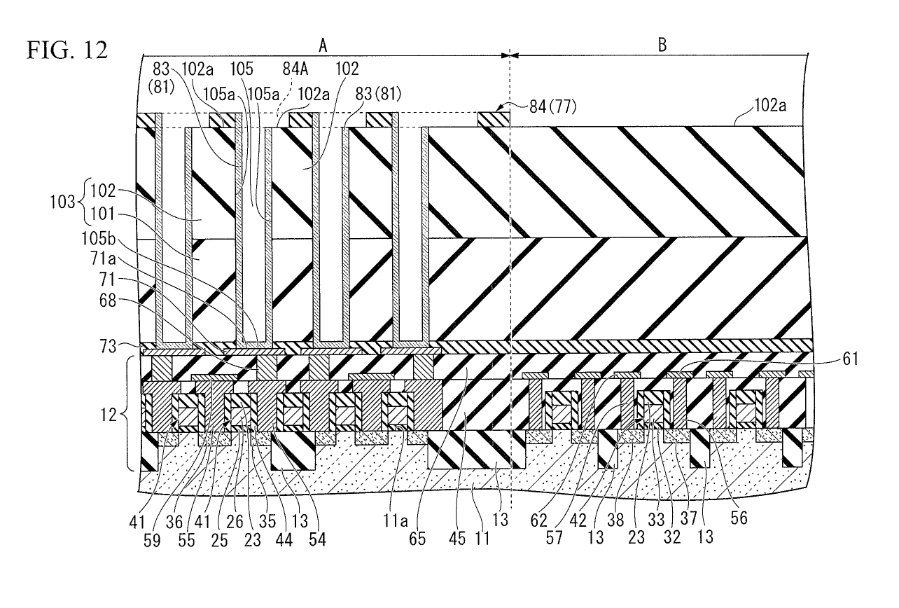

In the process shown in FIG. 12, the same processing is performed that is shown in FIG. 6A and FIG. 6B regarding the first embodiment, so as to formed a lower electrode 83 made of the conducting film 81 on the inside surface of the plurality of holes 105.

Subsequently, a support film 84 is formed having the support film formation insulating film 77 as a base material and linking to upper ends of the plurality of lower electrode 83, and that has an aperture part 84A that exposes a part of the upper surface 75a of the sacrificial insulating film 75 positioned between the plurality of lower electrodes 83. At this stage, the entire upper surface 102a of the second sacrificial insulating film 102 formed in the peripheral circuit region B is exposed from the support film 84.

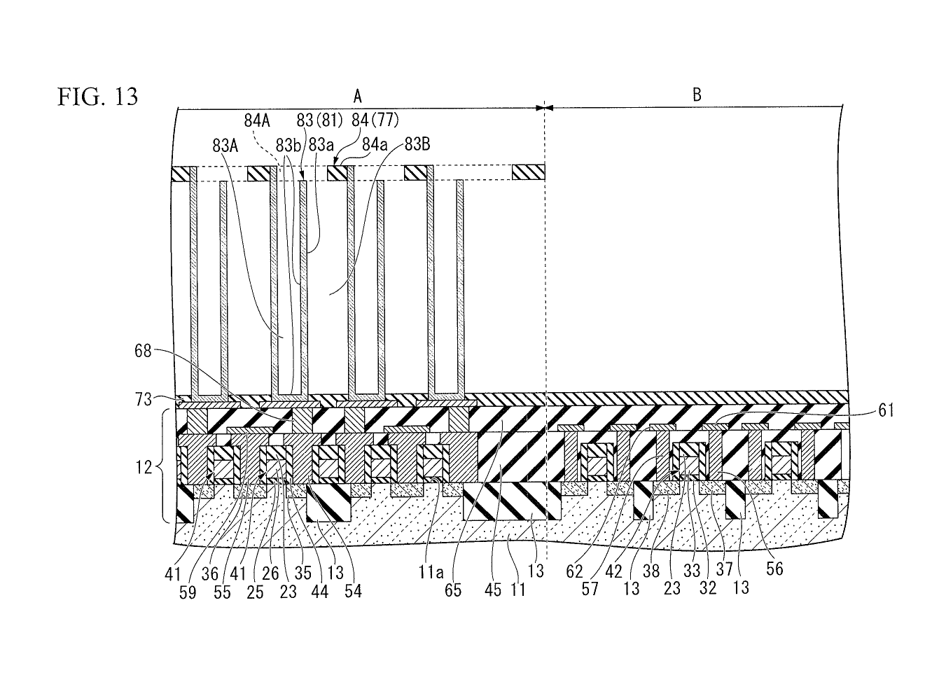

In the process shown in FIG. 13, the sacrificial insulating film 103 covering the outer wall of the plurality of lower electrodes 83 (conducting film 81) shown in FIG. 12 is removed, so as to expose the plurality of lower electrodes 83.

Specifically, wet etching under conditions in which the support film 84 and the etching stopper film 73 are more difficult to etch than the sacrificial insulating film 103 is done to remove the remove the sacrificial insulating film 103 that remained in the memory cell region A and the peripheral circuit region B shown in FIG. 12, so as to expose the upper surface 73a of the etching stopper film 73 and the outer wall surface 83a of the plurality of lower electrodes 83.

When this is done, because the etching stopper film 73 functions as an etching stopper, it is possible to suppress damage by the above-noted wet etching to the circuit element layer 12 formed below the etching stopper film 73 (specifically, the etching of the second interlayer insulating film 65). Hydrogen fluoride solution (HF solution), for example, can be used as the etching chemical for the wet etching.

In this manner, the first sacrificial insulating film 101 is formed on the upper surface 73a of the etching stopper film 73 by plasma CVD that uses a raw material that does not include a carbon component, after which a second sacrificial insulating film 102 is formed on the first sacrificial insulating film 101 by high-density plasma CVD that uses a raw material that does not include a carbon component, thereby forming a sacrificial insulating film 103 constituted by the laminated first sacrificial insulating film 101 and second sacrificial insulating film 102. Then, a hole 105 passing through the sacrificial insulating film 103 is formed, after which, of the sacrificial insulating film 103, a lower electrode 83 made of a conducting film 81 is formed that covers the side wall part 105a and the bottom surface 105b of the hole 105, and then the sacrificial insulating film 103 is removed, so that there is no attachment to the conducting film 81 of a residue caused by a carbon component after the removal of the sacrificial insulating film 103.

It is therefore possible to suppress poor formation of the capacitor insulating film 86 and the upper electrode 92 that are formed on the surface of the lower electrode 83 (the surface that includes the outer wall surface 83a and the inner surface 83b of the lower electrode 83) and to improve the capacitance value, while reducing the leakage of the stored electrical charge.

Since the characteristics of the capacitor 95 that is constituted by the lower electrode 83, the capacitor insulating film 86, and the upper electrode 92 are improved, the yield of the semiconductor device 100 can be improved refer FIG. 14, described later.

In the process shown in FIG. 14, by performing the same processing as shown in FIG. 8 of the already-described first embodiment, the upper surface 73a of the etching stopper film 73 which is formed in the memory cell region A and the peripheral circuit region B, the surface (the surface that includes the outer wall surface 83a and the inner surface 83b) of the lower electrode 83, and capacitor insulating film 86 that covers the surface of the support film 84a, a first conducting film 87 that covers the upper surface 86a of the capacitor insulating film 86, and a second conducing film 88 that covers the upper surface 87a of the first conducting film 87 are sequentially formed.

When this is done, the first and second conducting films 87 and 88 are formed to a thickness that fills the space 83A within the lower electrode 83 in which the capacitor insulating film 86 is formed, and the space 83B between the lower electrodes 83 in which the capacitor insulating film 86 is formed. The second conducting film 88 is formed so that the upper surface 88a thereof is flat.

The first and second conducting films 87 and 88 are formed also on the surface of the capacitor insulating film 86 (not shown) formed in the peripheral circuit region B.

After this is done, by anisotropic etching (specifically, dry etching) in the same manner as in the process step as shown in FIG. 8 according to the first embodiment, the capacitor insulating film 86, the first conducting film 87, and the second conducting film 88 formed on the peripheral circuit region B are selectively removed.

A plurality of capacitors 95 having a lower electrode 83, a capacitor insulating film 86, and an upper electrode 92 made of an upper electrode body 89 made of the first conducting film 87 that serves as the base material, and the upper electrode 92 which is constituted by the plate electrode 91 made of the second conducting film 88 that serves as the base material are formed in the memory cell region A.

Also, although it is not illustrated, a third interlayer insulating film (for example, a silicon oxide film (SiO₂ film) is deposited from the upper surface side of the structure shown in FIG. 14, after which CMP is used to polish the upper surface side of the third interlayer insulating film, so as to form an upper surface that is positioned above the upper surface 88a of the second conducting film 88 and also that is flat on the third interlayer insulating film.

A contact plug (not shown) that passes through the third interlayer insulating film and that also reaches the first interconnect 61 disposed in the peripheral circuit region B, and a contact plug (not shown) that passes through the third interlayer insulating film and also that reaches the second interconnect 62 disposed in the peripheral circuit region B are formed.

Subsequently, of the upper surface of the third interlayer insulating film, an interconnect (not shown) that is electrically connected to the upper electrode 92 is formed on the surface at a position in the memory cell region A and, of the upper surface of the third interlayer insulating film, an interconnect (not shown) is formed that is connected to a contact plug (not shown) passing through the third interlayer insulating film on the surface at a position in the peripheral circuit region B.

The semiconductor device 100 of the first embodiment is manufactured. In FIG. 14, the above-noted third interlayer insulating film, the contact plug passing through the above-noted third interlayer insulating film, and the interconnect formed on the third interlayer insulating film are omitted.

According to the method for manufacturing a semiconductor device of the second embodiment, using plasma CVD that uses a raw material that does not include a carbon component, a first sacrificial insulating film 101 is formed on the upper surface 73a of the etching stopper film 73. By high-density plasma CVD using a raw material that does not include a carbon component, a second sacrificial insulating film 102 having an etching rate that is slower than that of the first sacrificial insulating film 101 is laminated on the upper surface 101a of the first sacrificial insulating film 101, after which, when a sacrificial insulating film 103 made of the first and second sacrificial insulating films 101 and 102 is dry etched to form a hole 105 that exposes the upper surface 71a of the capacitor contact pad 71, by the second sacrificial insulating film 102 it is possible to suppress the lateral widening of an aperture diameter in the top part of the hole 105, and also the etching rate when the bottom of the hole 105 is formed is improved, and dry etching is facilitated.

Even in the case of forming a plurality of closely spaced holes 105 having a small aperture diameter, it is possible to suppress contacting between adjacent holes 105, and it is also possible to cause the bottom of the hole 105 to precisely reach the upper surface 71a of the capacitor contact pad 71 within the surface of the semiconductor substrate 11.

Therefore, even in the case for forming a plurality of closely spaced holes 105 having a small aperture diameter using a dry etching, it is possible to suppress contacting between lower electrodes 83 that are formed in adjacent holes 105, and also to improve the electrical connection reliability between the bottom end of the lower electrode 83 formed in the hole 105 and the capacitor contact pad 71, thereby enabling an improvement in the yield of the semiconductor device 100 according to the second embodiment.

According to a semiconductor device of the second embodiment, using plasma CVD that uses a raw material that does not include a carbon component, a sacrificial insulating film 101 is formed on the upper surface 73a of the etching stopper film 73. High-density plasma CVD using a raw material that does not include a carbon component, a second sacrificial insulating film 102 having an etching rate that is slower than that of the first sacrificial insulating film 101 is laminated on the upper surface 101a of the first sacrificial insulating film 101, thereby forming a sacrificial insulating film 103 made of the first and second sacrificial insulating films 101 and 102, after which a hole 105 passing through the sacrificial insulating film 103 is formed, and then, of the sacrificial insulating film 103, a lower electrode 83 made of the conducting film 81 is formed that covers the side wall part 105a and the bottom surface 105b of the hole 105, after which the sacrificial insulating film 103 is removed, so that it is possible to reduce the residue caused by a carbon component being attached to the conductive film 81 after the removal of the sacrificial insulating film 103.

Therefore, it is possible to suppress the poor formation of the capacitor insulating film 86 and the upper electrode 92 that are formed on the surface of the lower electrode 83 (the surface that includes the outer wall surface 83a and the inner surface 83b of the lower electrode 83) and to improve the capacitance value, while reducing the leakage of the stored electrical charge.

Since the characteristics of the capacitor 95 that is constituted by the lower electrode 83, the capacitor insulating film 86, and the upper electrode 92 are improved, the yield of the semiconductor device 100 can be improved (refer to FIG. 14 described later).

Although the second embodiment is described for an example in which plasma CVD using monosilane (SiH₄), which is a raw material that does not include carbon, and a raw material that includes nitrogen oxide (N₂O) are used to form a first sacrificial insulating film 101, and high-density plasma CVD using monosilane (SiH₄), which is a raw material that does not include a carbon component, and O₂ (a raw material that includes oxygen) is used to form a second sacrificial insulating film 102, high-density plasma CVD using monosilane (SiH₄), which is a raw material that does not include a carbon, and O₂ (a raw material that includes oxygen) may be used to form the first sacrificial insulating film 101 and monosilane (SiH₄), which is a raw material that does not include carbon, and a raw material that includes nitrogen oxide (N₂O), may be used in the forming the second sacrificial insulating film 102.

In this case, because there is no residue caused by a carbon component being attached to the conductive film 81 after the removal of the sacrificial insulating film 103, the yield of the semiconductor device 100 can be improved.

Also, there are cases in which, of the memory cell region A, a conducting film that constitutes the lower electrode, the capacitor insulating film, and a guard ring made of a conducting film that constitutes the upper electrode are formed so as to surround one the same group of memory cells, with the only the part of the sacrificial insulating film formed at a position inside the guard ring being removed.

Even in the above-noted case, it is possible to apply the method for manufacturing the semiconductor device 100 of the second embodiment, and it is possible to achieve the same type of effect as the semiconductor device 100 according to the first embodiment.

The application of the method for manufacturing the semiconductor device 100 according to the second embodiment when applied to a semiconductor device 100 according to the second embodiment having a structure in which the guard ring is not formed has a greater effect, because more of the sacrificial insulating film 103 is removed.

### Third Embodiment

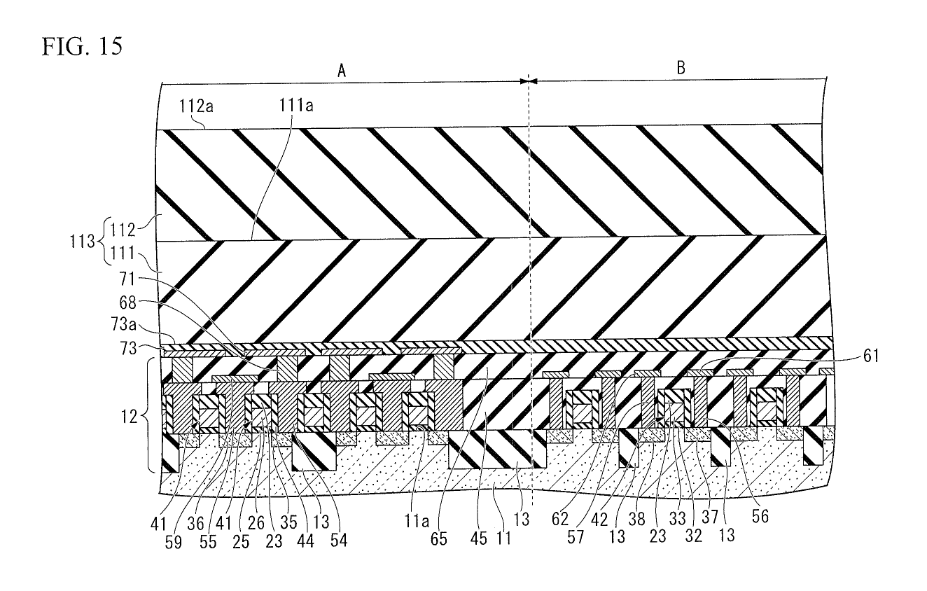

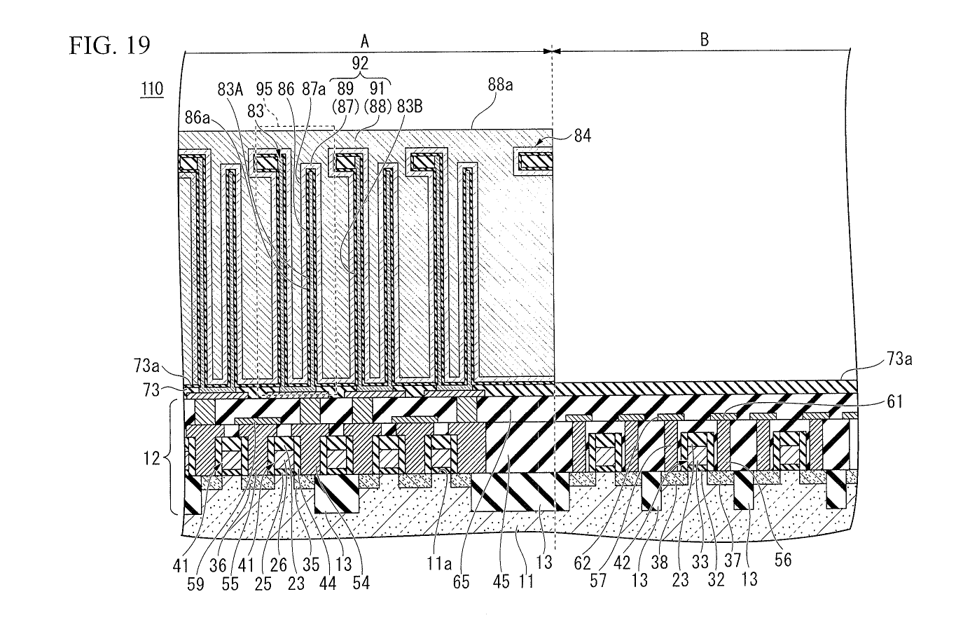

FIG. 15 to FIG. 19 are cross-sectional views of the manufacturing processes for a semiconductor device according to the third embodiment of the present invention. In FIG. 15 to FIG. 19, a DRAM (dynamic random access memory) is illustrated as an example of the semiconductor device 110 (refer to FIG. 19) according to the third embodiment, which is described below. In FIG. 15 to FIG. 19, constituent elements that are the same as those in the semiconductor device 10 of the above-described first embodiment are assigned the same reference numerals.

Referring to FIG. 15 to FIG. 19, the method for manufacturing the semiconductor device 110 according to the third embodiment will be described below.

First, in the process shown in FIG. 15, using a method similar to that described regarding FIG. 2 in the first embodiment, a circuit element layer 12, a capacitor contact pad 71, and an etching stopper film 73 are sequentially formed on the upper surface 11a of the semiconductor substrate 11.

Using plasma CVD, with a raw material including carbon, such as TEB (triethyl boron), TEPO (triethyl phosphate), TEOS (tetraethoxy silane), or O₃, a first sacrificial insulating film 111 (for example having a thickness of 0.6 μm) is formed that covers the upper surface 73a of the etching stopper film 73.

In this case, the film deposition conditions for the first sacrificial insulating film 111 can be, for example, a semiconductor substrate 11 temperature of 450 to 500° C., a TEB flow amount of 400 to 450 sccm, a TEPO flow amount of 100 to 150 sccm, a TEOS flow amount of 2000 to 2500 sccm, an O₃ flow amount of 13,000 to 15,000 sccm, and a deposition chamber internal pressure of 26667 Pa.

Plasma CVD using monosilane (SiH₄), which is a raw material that does not include carbon, and a raw material that includes nitrogen oxide (N₂O) is used to form a second sacrificial insulating film 112 (to a thickness of, for example, 0.8 μm) made of a silicon oxide film (SiO₂ film), so as to cover the upper surface 111a of the first sacrificial insulating film 111.

In this case, the deposition conditions for the second sacrificial insulating film 112 can be, for example, a semiconductor substrate 11 temperature of 350 to 400° C., a monosilane (SiH₄) flow amount of 500 to 600 sccm, an N₂O flow amount of 8,000 to 10,000 sccm, and a deposition chamber internal pressure of 360 Pa.

In this case, the deposition conditions for the second sacrificial insulating film 112 can be, for example, a semiconductor substrate 11 temperature of 350 to 400° C., a monosilane (SiH₄) flow amount of 500 to 600 sccm, an N₂O flow amount of 8,000 to 10,000 sccm, and a deposition chamber internal pressure of 360 Pa.

The sacrificial insulating film 113 according to the third embodiment has small amount of carbon contained in the film compared to the case of formation using only a raw material including carbon.

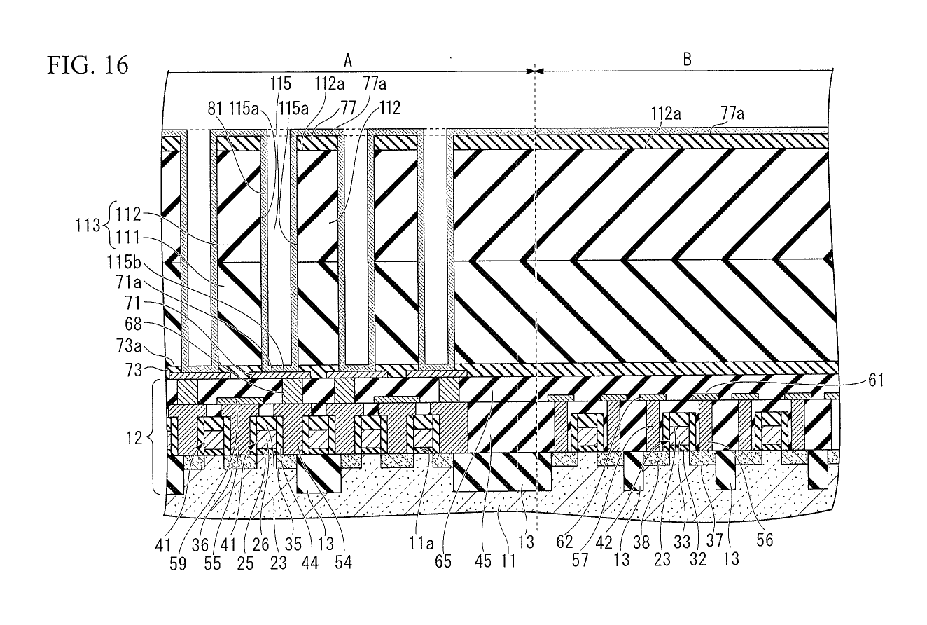

In the process shown in FIG. 16, by performing the same processing as shown in FIG. 3 that was described regarding the first embodiment, a support film formation insulating film 77 is formed.

Photoresist and anisotropic etching (dry etching) are used to form a hole 115 that exposes the upper surface 71a of the capacitor contact pad 71 and passes through a part of the sacrificial insulating film 113 and a part of the support film formation insulating film 77 that is positioned above the capacitor contact pad 71. The hole 115 is formed with respect to each of the plurality of capacitor contact pads 71.

The second sacrificial insulating film 112 made of a silicon oxide film (SiO₂ film) that is formed by plasma CVD has an etching rate that is slower than that of the first sacrificial insulating film 111 made of BPSF film.

For this reason, the sacrificial insulating film 113 made of the first and second sacrificial insulating films 111 and 112 is dry etched to form a hole 115 that exposes the upper surface 71a of the capacitor contact pad 71, so that by the second sacrificial insulating film 112 it is possible to suppress the lateral widening of an aperture diameter in the top part of the hole 115, and also the etching rate when the bottom of the hole 115 is formed is improved, and dry etching is facilitated.

Even in the case of forming a plurality of closely spaced holes 115 having a small aperture diameter, it is possible to suppress contacting between adjacent holes 115, and it is also possible to cause the bottom of the hole 115 to precisely reach the upper surface 71a of the capacitor contact pad 71 within the surface of the semiconductor substrate 11.

Therefore, even in the case for forming a plurality of closely spaced holes 115 having a small aperture diameter using a dry etching, it is possible to suppress contacting between lower electrodes 83 that are formed in adjacent holes 115, and also improve the electrical connection reliability between the bottom end of the lower electrode 83 formed in the hole 115 and the capacitor contact pad 71, thereby enabling an improvement in the yield of the semiconductor device 110 according to the third embodiment.

From the upper surface side of the structure shown in FIG. 16, of the upper surface 71a of the capacitor contact pad 71 opposite the bottom surface 115b of the hole 115 and the sacrificial insulating film 113, a conducting film 81 is formed so as to cover the side wall part 115a of the hole 115 (specifically, the etching stopper film 73 exposed in the hole 115, and the side wall parts of the sacrificial insulating film 113 and the support film formation insulating film 77).

Specifically, for example, using CVD, by sequentially laminating a titanium film (Ti film) and a titanium nitride film (TiN film), a conducting film 81 made of the titanium film (Ti film) and the titanium nitride film (TiN film) is formed. When this is done, the conducting film 81 is formed also on the upper surface 77a of the support film formation insulating film 77.

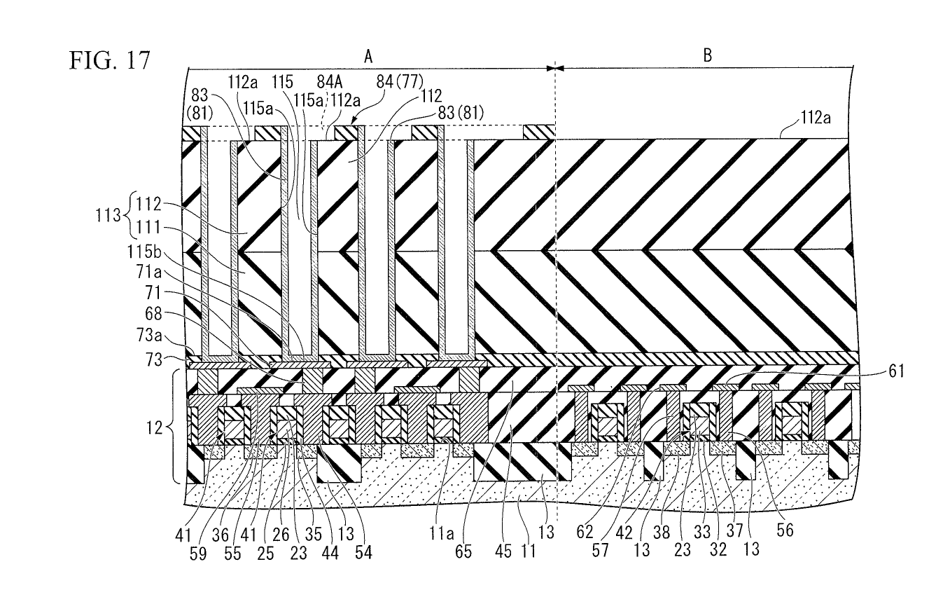

In the process shown in FIG. 17, the same process as in shown in FIG. 6A and FIG. 6B according to the first embodiment described earlier is performed, thereby forming a lower electrode 83 made of the conducting film 81 on the inner surface of the plurality of holes 115, after which a support film 84 having the support film formation insulating film 77 as a base material, linking to the upper ends of the plurality of lower electrodes 83, and having an aperture 84A that exposes a part of the upper surface 112a of the second sacrificial insulating 112 positioned between the plurality of lower electrodes 83 is formed.

In this process, the entire surface of the upper surface 112 of the second sacrificial insulating film 112 formed on the peripheral circuit region B is exposed from the support film 84.

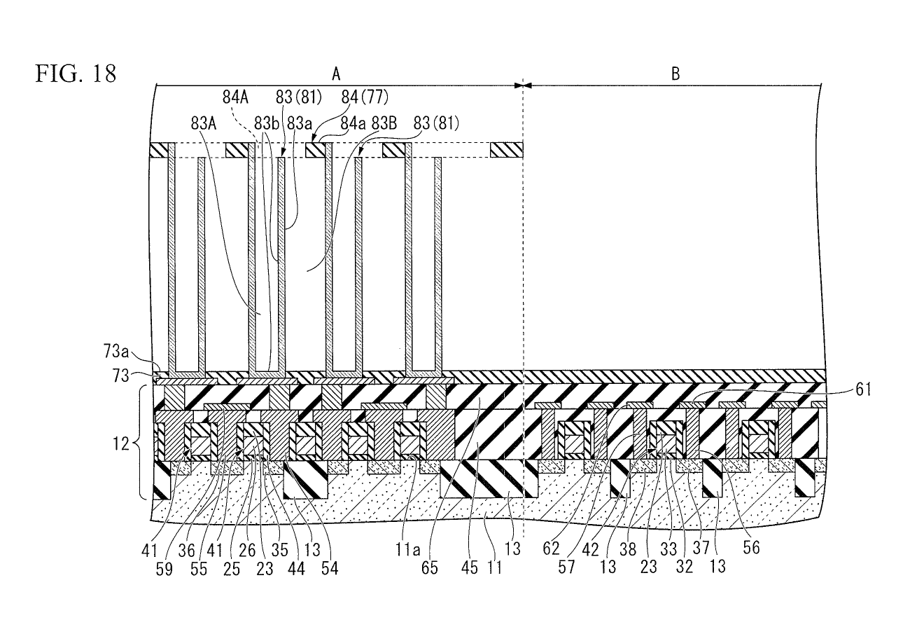

In the process shown in FIG. 18, the sacrificial insulating film 103 that covers the outer wall of a plurality of the lower electrodes 83 (conducting film 81) shown in FIG. 17 is removed, thereby exposing a plurality of lower electrodes 83.

Specifically, wet etching under conditions in which the support film 84 and the etching stopper film 73 are more difficult to etch than the sacrificial insulating film 113 is done to remove sacrificial insulating film 113 remaining in the memory cell region A and the peripheral circuit region B shown in FIG. 17, so as to expose the upper surface 73a of the etching stopper film 73 and the outer wall surface 83a of the lower electrode 83.

Specifically, wet etching under conditions in which the support film 84 and the etching stopper film 73 are more difficult to etch than the sacrificial insulating film 113 is done to remove sacrificial insulating film 113 remaining in the memory cell region A and the peripheral circuit region B shown in FIG. 17, so as to expose the upper surface 73a of the etching stopper film 73 and the outer wall surface 83a of the lower electrode 83.

In this manner, the first sacrificial insulating film 111 is formed on the upper surface 73a of the etching stopper film 73 using a raw material that includes a carbon component, and the second sacrificial insulating film 102 is then formed on the upper surface 111a of the first sacrificial insulating film 111 using a raw material that does not include a carbon component, after which a hole 115 is formed that passes through the sacrificial insulating film 103 made of laminated first and second sacrificial insulating films 101 and 102. Then, of the sacrificial insulating film 113, a lower electrode 83 made of the conducting film 81 is formed that covers the side wall part 115a and the bottom surface 115b of the hole 115, after which the sacrificial insulating film 113 is removed by wet etching. It is possible to reduce the removal amount of the sacrificial insulating film including more carbon than in the conventional amount.

It is possible to suppress the residue caused by a carbon component being attached to the lower electrode 83 made of the conductive film 81 after the removal of the sacrificial insulating film 113, and it is thus possible to suppress the poor formation of the capacitor insulating film 86 (refer to FIG. 19) that is formed on the surface of the lower electrode 83 (the surface that includes the outer wall surface 83a and the inner surface 83b of the lower electrode 83).

Since the characteristics of the capacitor 95 that is constituted by the lower electrode 83, the capacitor insulating film 86, and the upper electrode 92 are improved, the yield of the semiconductor device 110 according to the third embodiment can be improved (refer FIG. 19, described later).

In the process shown in FIG. 19, by performing the same processing as shown in FIG. 8 of the already-described first embodiment, the upper surface 73a of the etching stopper film 73 which is formed in the memory cell region A and the peripheral circuit region B, the surface (the surface that includes the outer wall surface 83a and the inner surface 83b) of the lower electrode 83, and the capacitor insulating film 86 that covers the upper surface of the support film 84a, a first conducting film 87 that covers the upper surface 86a of the capacitor insulating film 86, a second conducing film 88 that covers the upper surface 87a of the first conducting film 87 are sequentially formed.

When this is done, the first and second conducting films 87 and 88 are formed to a thickness that fills the space 83A within the lower electrode 83 in which the capacitor insulating film 86 is formed, and the space 83B between the lower electrodes 83 in which the capacitor insulating film 86 is formed. The second conducting film 88 is formed so that the upper surface 88a thereof is flat.

The first and second conducting films 87 and 88 are formed also on the surface of the capacitor insulating film 86 (not shown) formed in the peripheral circuit region B.

By anisotropic etching (specifically, dry etching) in the same manner with the process step as shown in FIG. 8 according to the first embodiment, the capacitor insulating film 86, the first conducting film 87, and the second conducting film 88 formed on the peripheral circuit region B are selectively removed.

A plurality of capacitors 95 having a lower electrode 83, a capacitor insulating film 86, and an upper electrode 92 made of an upper electrode body 89 made of the first conducting film 87 that serves as the base material, and the upper electrode 92 which is constituted by the plate electrode 91 made of the second conducting film 88 that serves as the base material are formed in the memory cell region A.

Although it is not illustrated, after formation of the capacitor 95, the following process is actually done.

A third interlayer insulating film (for example, a silicon oxide film (SiO₂ film) is deposited from the upper surface side of the structure shown in FIG. 19, after which CMP is used to polish the upper surface side of the third interlayer insulating film, so as to form an upper surface that is positioned above the upper surface 88a of the second conducting film 88, and also that is planarized, on the third interlayer insulating film.

A contact plug (not shown) that passes through the third interlayer insulating film and that also reaches the first interconnect 61 disposed in the peripheral circuit region B, and a contact plug (not shown) that passes through the third interlayer insulating film and also that reaches the second interconnect 62 disposed in the peripheral circuit region B are formed.

Subsequently, of the upper surface of the third interlayer insulating film, an interconnect (not shown) that is electrically connected to the upper electrode 92 is formed on the surface at a part positioned in the memory cell region A and, of the upper surface of the third interlayer insulating film, an interconnect (not shown) is formed that is connected to a contact plug (not shown) passing through the third interlayer insulating film on the surface at a part positioned in the peripheral circuit region B.

The semiconductor device 110 of the third embodiment is manufactured. In FIG. 19, the above-noted third interlayer insulating film, the contact plug passing through the above-noted third interlayer insulating film, and the interconnect formed on the third interlayer insulating film are omitted.

According to a method of manufacturing the semiconductor in the third embodiment, the first sacrificial insulating film 111 is formed on the upper surface 73a of the etching stopper film 73 using a raw material that includes a carbon component, and the second sacrificial insulating film 102 is then formed on the upper surface 111a of the first sacrificial insulating film 111 using a raw material that does not include a carbon component, after which a hole 115 is formed that passes through the sacrificial insulating film 113 made of laminated first and second sacrificial insulating films 111 and 112. Then, of the sacrificial insulating film 113, a lower electrode 83 made of the conducting film 81 is formed that covers the side wall part 115a and the bottom surface 115b of the hole 115, after which the sacrificial insulating film 113 is removed. By doing this, it is possible to reduce the removal amount of the sacrificial insulating film including more carbon than in the conventional amount.

Since it is possible to suppress the residue caused by a carbon component being attached to the lower electrode 83 made of the conductive film 81 after the removal of the sacrificial insulating film 113, and thus it is possible to suppress the poor formation of the capacitor insulating film 86 and upper electrode 92 that are formed on the surface of the lower electrode 83 (the surface that includes the outer wall surface 83a and the inner surface 83b of the lower electrode 83) and to improve the capacitance value, while reducing the leakage of the stored electrical charge.

Since the characteristics of the capacitor 95 that is constituted by the lower electrode 83, the capacitor insulating film 86, and the upper electrode 92 are improved, the yield of the semiconductor device 110 can be improved (refer FIG. 8) described later.

Although the third embodiment is described referring to a case in which, using plasma CVD, with a raw material including carbon, such as TEB, TEPO, TEOS, or O₃, a first sacrificial insulating film 111 that is made from BPSG film is formed so as to cover the upper surface 73a of the etching stopper film 73, and using plasma CVD with monosilane (SiH₄), which is a raw material that does not include carbon, and a raw material that includes nitrogen oxide (N₂O) is used to form a second sacrificial insulating film 112 made of silicone oxide film (SiO₂ film) so as to cover the upper surface 111a of the first sacrificial insulating film, alternatively, plasma CVD with monosilane (SiH₄), which is a raw material that does not include carbon, and a raw material that includes nitrogen oxide (N₂O) may be used to form a first sacrificial insulating film 111 that covers the upper surface 73a of the etching stopper film 73, after which the second sacrificial insulating film 112 may be formed by plasma CVD using with a raw material including carbon, such as TEB, TEPO, TEOS, or O₃.

In this case, because the removal amount of the sacrificial insulating film including more carbon than that of conventional amount becomes small, it is possible to suppress the residue caused by a carbon component being attached to the lower electrode 83 made of the conductive film 81 after the removal of the sacrificial insulating film. It is thus possible to suppress the poor formation of the capacitor insulating film 86 and upper electrode 92 that are formed on the surface of the lower electrode 83 (the surface that includes the outer wall surface 83a and the inner surface 83b of the lower electrode 83) and to improve the capacitance value, while reducing the leakage of the stored electrical charge, thereby enabling an improvement in the yield of the semiconductor device 110.

Also, either one of the first and second sacrificial insulating films 111 and 112 insulating films constituting the sacrificial insulating film 113, may be deposited by a raw material including carbon, the remaining insulating film being deposited by a raw material not including carbon.

Furthermore, the deposition method using a raw material not including carbon is not restricted by plasma CVD using a raw material including the above-described monosilane (SiH₄) and nitrogen oxide (N₂O). For example, high-density plasma CVD using monosilane (SiH₄) and oxygen (O₂) (a raw material that includes oxygen) may be used as described the first embodiment.

Also, a deposition method using a raw material that does not include carbon is not restricted by the method for forming BPSG film that is described above. For example, a TEOS film may be formed using a raw material not including carbon.

As used herein, the following directional terms “forward, rearward, above, downward, vertical, horizontal, below, and transverse” as well as any other similar directional terms refer to those directions of an apparatus equipped with the present invention. Accordingly, these terms, as utilized to describe the present invention should be interpreted relative to an apparatus equipped with the present invention.

Furthermore, the particular features, structures, or characteristics may be combined in any suitable manner in one or more embodiments.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

It is apparent that the present invention is not limited to the above embodiments, but may be modified and changed without departing from the scope and spirit of the invention.

What is claimed is:

1. A method of forming a semiconductor device, the method comprising:
forming a dummy insulating film over a semiconductor substrate by using a source material that is free of carbon as an essential component;
forming a hole that penetrates the dummy insulating film;
forming a conductive film that covers a side wall of the hole of the dummy insulating film; and
removing the dummy insulating film to expose an outer surface of the conductive film.

2. The method according to claim 1, wherein forming the dummy insulating film comprises:
carrying out a plasma chemical vapor deposition method using a source material comprising monosilane and nitrogen oxide.

3. The method according to claim 1, wherein forming the dummy insulating film comprises:
carrying out a high density plasma chemical vapor deposition method using a source material comprising monosilane and oxygen.

4. The method according to claim 1, further comprising:
forming a second dummy insulating film by using a carbon-containing source material, the second dummy insulating film being contact to the first dummy insulating film,
wherein the hole penetrates the first and second dummy insulating films.

5. The method according to claim 1, wherein forming the dummy insulating film comprises:
forming a first dummy insulating layer; and
forming a second dummy insulating layer on the first dummy insulating layer,
wherein the hole penetrates the first and second dummy insulating layers,
wherein a first one of forming the first dummy insulating layer and forming the second dummy insulating layer is carried out using a source material comprising monosilane and nitrogen oxide, and
wherein a second one of forming the first dummy insulating layer and forming the second dummy insulating layer is carried out using a source material comprising monosilane and oxygen.

6. The method according to claim 5, wherein forming the hole comprises:
carrying out an anisotropic etching process to selectively etch the first and second dummy insulating layers,
wherein the anisotropic etching process for selectively etching the second dummy insulating layer is varied out at a slower etching rate than that of the anisotropic etching process for selectively etching the first dummy insulating layer.

7. The method according to claim 1, wherein removing the dummy insulating film comprises:
removing at least a portion of the dummy insulating film, the portion covering an outside surface of the conductive film, to expose the outside surface of the conductive film.

8. The method according to claim 1, wherein the dummy insulating film is removed after the conductive film is formed.

9. The method according to claim 1, further comprising:
forming a circuit element layer over the semiconductor substrate before forming the dummy insulating film, the circuit element layer comprising a cell region and a peripheral circuit region, the cell region including a cell transistor, the peripheral circuit region including a peripheral transistor;
forming a capacitive contact pad on the cell region of the circuit element layer, the capacitive contact pad being coupled to the cell transistor; and
forming an etching stopper film covering the capacitive contact pad and the circuit element layer,
wherein the dummy insulating film is formed on the etching stopper film, and the etching stopper film is lower in etching rate than the dummy insulating film.

10. The method according to claim 9, further comprising:
forming a support film formation insulating film on the dummy insulating film, the support film formation insulating film being lower in etching rate than the dummy insulating film.

11. The method according to claim 10, wherein forming the hole comprises:
forming a hole which penetrates the support film formation insulating film, the dummy insulating film and the etching stopper film, so that the hole reaches an upper surface of the capacitive contact pad.

12. The method according to claim 11, wherein forming the conductive film comprises:
forming the conductive film which covers the side wall of the hole of the etching stopper film, the dummy insulating film, and the support film formation insulating film, the conductive film covering the capacitive contact pad at the bottom of the hole.

13. The method according to claim 12, wherein forming at least a hole comprises forming a plurality of holes,
wherein forming the at least one conductive film comprises forming a plurality of conductive films, and
wherein the method further comprises:
forming a plurality of capacitive insulating films on the plurality of conductive film; and
forming a plurality of top electrodes on the plurality of capacitive insulating films to form a plurality of capacitors which include the conductive films as bottom electrodes.

14. The method according to claim 13, further comprising:
forming a support film by patterning the support film formation insulating film, after forming the plurality of conductive films and before removing the dummy insulating film, the support film connecting the plurality of conductive films as the bottom electrodes.

15. The method according to claim 14, wherein forming the support film comprises:
removing the support film formation insulating film entirely in the peripheral circuit region and selectively in the cell region to expose an upper surface of the dummy insulating film in the peripheral circuit region and to expose parts of the upper surface of the dummy insulating film in the cell region, the parts of the upper surface being positioned under gaps between the bottom electrodes.

16. The method according to claim 15, wherein removing the dummy insulating film comprises:
carrying out a wet etching process under conditions such that the support film and the etching stopper film are lower in etching rate than the dummy insulating film, to expose an upper surface of the etching stopper film and outside surfaces of the bottom electrodes.

17. The method according to claim 16, wherein forming the plurality of capacitive insulating films comprises:
forming the capacitive insulating film which covers the upper surface of the etching stopper film, the bottom electrodes and the support film; and
forming the top electrode which covers the capacitive insulating film.

18. The method according to claim 17, wherein forming the top electrode comprises:
forming the top electrode which fills inner spaces of the bottom electrodes covered by the capacitive insulating film, the top electrode also filling gaps between the bottom electrodes covered by the capacitive insulating film, and the top electrode having a flat top surface.

19. A method of forming a semiconductor device, the method comprising:
forming a dummy insulating film over a semiconductor substrate by using a carbon-free source material without using any carbon-containing source material;
forming a hole that penetrates the dummy insulating film;
forming a conductive film that covers a side wall of the hole of the dummy insulating film; and
removing the dummy insulating film to expose an outer surface of the conductive film.

20. A method of forming a semiconductor device, the method comprising:
forming a dummy insulating film over a semiconductor substrate by using a source material that is free of carbon as an essential component;
forming a hole that penetrates the dummy insulating film;
forming a conductive film having a first surface on a side wall of the hole; and
removing the dummy insulating film to remain the conductive film and to expose the first surface of the conductive film.
